(19) United States
(12) Patent Application Publication
(10) Pub. No.: US 2020/0082239 A1
(43) Pub. Date: Mar. 12, 2020

(54) SYSTEM AND METHOD FOR RFID TAG INTERFACING

(71) Applicants: Philip Li, Richmond, TX (US); Marko Bajkovic, Valley Village, CA (US)

(72) Inventors: Philip Li, Richmond, TX (US); Marko Bajkovic, Valley Village, CA (US)

(21) Appl. No.: 16/129,335

(22) Filed: Sep. 12, 2018

(51) Int. Cl. G06K 19/077; H01L 23/31; H01L 23/495; H01L 29/45; H01L 29/49; H01L 29/24; H01L 29/786; H01L 49/02; H01L 21/48; H01L 21/56; H01L 21/445; H01L 21/02; H01L 21/477; H01L 29/66

(52) U.S. Cl. CPC G06K 19/07722; H01L 29/66969; H01L 23/49562; H01L 23/49572; H01L 29/45; H01L 29/4908; H01L 29/24; H01L 29/7869; H01L 28/20; H01L 21/4821; H01L 21/565; H01L 21/445; H01L 21/02164; H01L 21/02178; H01L 21/02181; H01L 21/02189; H01L 21/477; H01L 21/02565; H01L 21/02628; H01L 23/3107

(57) ABSTRACT

A system and method comprising depositing a first layer on a substrate, in which the first layer comprises at least one of, a metal oxide and carbon based derivative, wherein the first layer is a gate electrode of a tag. Depositing a second layer, annealing said second layer, and treating a surface of the second layer, wherein the surface treatment is configured to enhance conductivity. Depositing a third layer, wherein the third layer is a gate dielectric of the tag. Depositing a fourth and a fifth layer. The fifth layer comprises at least an Indium Gallium Zinc Oxide layer and as a semiconductor layer of the tag. Photonic curing the fifth layer. Depositing a sixth and a seventh layer, in which the sixth layer is a source contact layer and said seventh layer is a drain contact layer of the tag.

### RELATED CO-PENDING U.S. PATENT APPLICATIONS

Not applicable.

### INCORPORATION BY REFERENCE OF SEQUENCE LISTING PROVIDED AS A TEXT FILE

Not applicable.

### FEDERALLY SPONSORED RESEARCH OR DEVELOPMENT

Not applicable.

### REFERENCE TO SEQUENCE LISTING, A TABLE, OR A COMPUTER LISTING APPENDIX

Not applicable.

### COPYRIGHT NOTICE

A portion of the disclosure of this patent document contains material that is subject to copyright protection by the author thereof. The copyright owner has no objection to the facsimile reproduction by anyone of the patent document or patent disclosure for the purposes of referencing as patent prior art, as it appears in the Patent and Trademark Office, patent file or records, but otherwise reserves all copyright rights whatsoever.

### BACKGROUND OF THE RELEVANT PRIOR ART

One or more embodiments of the invention generally relate to wireless interfacing. More particularly, certain embodiments of the invention relate to RFID tag interfacing.

The following background information may present examples of specific aspects of the prior art (e.g., without limitation, approaches, facts, or common wisdom) that, while expected to be helpful to further educate the reader as to additional aspects of the prior art, is not to be construed as limiting the present invention, or any embodiments thereof, to anything stated or implied therein or inferred thereupon.

The following is an example of a specific aspect in the prior art that, while expected to be helpful to further educate the reader as to additional aspects of the prior art, is not to be construed as limiting the present invention, or any embodiments thereof, to anything stated or implied therein or inferred thereupon. By way of educational background, an aspect of the prior art generally useful to be aware of is that while a process of RFID tag micro-fabrication has been known there is still much research conducted on ways to improve steps in a process to make or improve materials used. Typical RFID tags are built on silicon substrates. The silicon substrate and the processing steps on the silicon substrate are costly and make it unsuited for tagging items (such as automotive components) that require price points around 1 or 2 cents. Metal foil substrates are not typically used for RFID tags but are a good choice because they can be ultra-low cost, flexible, and be able to withstand high temperatures. Passive and active refer to two different types of RFID tags and are not related to the substrate. Active tags have a built in power supply and are able to send out information on its own. Passive tags do not have a power supply and require external transponders to send a signal to them first. The passive tag then uses this signal to power itself and send back information. The type of tag described in this patent is a passive tag. Furthermore, there are steps in a RFID tag micro-fabrication process which could be improved. Treating or curing steps for micro-fabrication usually have room for improvement. Furthermore, recent research on printed RFID tags are usually made from organic materials which have limitations, such as being unstable in atmospheric conditions and also suffering from low carrier mobilities slowing down a device. Organic RFID tags also suffer from sensitivities to the environment, are more prone to be unstable if left in the open air, and cannot operate at high frequencies or be read at long distances. Furthermore still, RFID tags are usually relatively expensive, and RFID tags are usually rigid and not flexible, severely limiting their applications.

In view of the foregoing, it is clear that these traditional techniques are not perfect and leave room for more optimal approaches.

### BRIEF DESCRIPTION OF THE DRAWINGS

The present invention is illustrated by way of example, and not by way of limitation, in the figures of the accompanying drawings and in which like reference numerals refer to similar elements and in which:

FIG. 1 illustrates a representative process flow diagram for building the transistor stack, in accordance with an embodiment of the invention;

FIG. 2 illustrates a cross-sectional view of structure for a fully printed inorganic passive RFID tag, in accordance with an embodiment of the invention;

FIG. 3 illustrates an exemplary software system modules architecture for an RFID tag;

FIG. 4 is a block diagram depicting an exemplary client/server system which may be used by an exemplary web-enabled/networked embodiment of the present invention; and,

FIG. 5 illustrates a block diagram depicting a conventional client/server communication system.

Unless otherwise indicated illustrations in the figures are not necessarily drawn to scale.

### DETAILED DESCRIPTION OF SOME EMBODIMENTS

The present invention is best understood by reference to the detailed figures and description set forth herein.

Embodiments of the invention are discussed below with reference to the Figures. However, those skilled in the art will readily appreciate that the detailed description given herein with respect to these figures is for explanatory purposes as the invention extends beyond these limited embodiments. For example, it should be appreciated that those skilled in the art will, in light of the teachings of the present invention, recognize a multiplicity of alternate and suitable approaches, depending upon the needs of the particular application, to implement the functionality of any given detail described herein, beyond the particular implementation choices in the following embodiments described and shown. That is, there are modifications and variations of the invention that are too numerous to be listed but that all fit within the scope of the invention. Also, singular words should be read as plural and vice versa and masculine as feminine and vice versa, where appropriate, and alternative embodiments do not necessarily imply that the two are mutually exclusive.

It is to be further understood that the present invention is not limited to the particular methodology, compounds, materials, manufacturing techniques, uses, and applications, described herein, as these may vary. It is also to be understood that the terminology used herein is used for the purpose of describing particular embodiments only, and is not intended to limit the scope of the present invention. It must be noted that as used herein and in the appended claims, the singular forms “a,” “an,” and “the” include the plural reference unless the context clearly dictates otherwise. Thus, for example, a reference to “an element” is a reference to one or more elements and includes equivalents thereof known to those skilled in the art. Similarly, for another example, a reference to “a step” or “a means” is a reference to one or more steps or means and may include sub-steps and subservient means. All conjunctions used are to be understood in the most inclusive sense possible. Thus, the word “or” should be understood as having the definition of a logical “or” rather than that of a logical “exclusive or” unless the context clearly necessitates otherwise. Structures described herein are to be understood also to refer to functional equivalents of such structures. Language that may be construed to express approximation should be so understood unless the context clearly dictates otherwise.

All words of approximation as used in the present disclosure and claims should be construed to mean “approximate,” rather than “perfect,” and may accordingly be employed as a meaningful modifier to any other word, specified parameter, quantity, quality, or concept. Words of approximation, include, yet are not limited to terms such as “substantial”, “nearly”, “almost”, “about”, “generally”, “largely”, “essentially”, “closely approximate”, etc.

As will be established in some detail below, it is well settled law, as early as 1939, that words of approximation are not indefinite in the claims even when such limits are not defined or specified in the specification.

For example, see Ex parte Mallory, 52 USPQ 297, 297 (Pat. Off. Bd. App. 1941) where the court said “The examiner has held that most of the claims are inaccurate because apparently the laminar film will not be entirely eliminated. The claims specify that the film is “substantially” eliminated and for the intended purpose, it is believed that the slight portion of the film which may remain is negligible. We are of the view, therefore, that the claims may be regarded as sufficiently accurate.”

Note that claims need only “reasonably apprise those skilled in the art” as to their scope to satisfy the definiteness requirement. See Energy Absorption Sys., Inc. v. Roadway Safety Servs., Inc., Civ. App. 96-1264, slip op. at 10 (Fed. Cir. Jul. 3, 1997) (unpublished) Hybridtech v. Monoclonal Antibodies, Inc., 802 F.2d 1367, 1385, 231 USPQ 81, 94 (Fed. Cir. 1986), cert. denied, 480 U.S. 947 (1987). In addition, the use of modifiers in the claim, like “generally” and “substantial,” does not by itself render the claims indefinite. See Seattle Box Co. v. Industrial Crating & Packing, Inc., 731 F.2d 818, 828-29, 221 USPQ 568, 575-76 (Fed. Cir. 1984).

Moreover, the ordinary and customary meaning of terms like “substantially” includes “reasonably close to: nearly, almost, about”, connoting a term of approximation. See In re Frye, Appeal No. 2009-006013, 94 USPQ2d 1072, 1077, 2010 WL 889747 (B.P.A.I. 2010) Depending on its usage, the word “substantially” can denote either language of approximation or language of magnitude. Deering Precision Instruments, L.L.C. v. Vector Distribution Sys., Inc., 347 F.3d 1314, 1323 (Fed. Cir. 2003) (recognizing the “dual ordinary meaning of the term “substantially” as connoting a term of approximation or a term of magnitude”). Here, when referring to the “substantially halfway” limitation, the Specification uses the word “approximately” as a substitute for the word “substantially” (Fact 4). (Fact 4). The ordinary meaning of “substantially halfway” is thus reasonably close to or nearly at the midpoint between the forwardmost point of the upper or outsole and the rearwardmost point of the upper or outsole.

Similarly, the term ‘substantially’ is well recognize in case law to have the dual ordinary meaning of connoting a term of approximation or a term of magnitude. See Dana Corp. v. American Axle & Manufacturing, Inc., Civ. App. 04-1116, 2004 U.S. App. LEXIS 18265, *13-14 (Fed. Cir. Aug. 27, 2004) (unpublished). The term “substantially” is commonly used by claim drafters to indicate approximation. See Cordis Corp. v. Medtronic AVE Inc., 339 F.3d 1352, 1360 (Fed. Cir. 2003) (“The patents do not set out any numerical standard by which to determine whether the thickness of the wall surface is ‘substantially uniform.’ The term ‘substantially,’ as used in this context, denotes approximation. Thus, the walls must be of largely or approximately uniform thickness.”); see also Deering Precision Instruments, LLC v. Vector Distribution Sys., Inc., 347 F.3d 1314, 1322 (Fed. Cir. 2003); Epcon Gas Sys., Inc. v. Bauer Compressors, Inc., 279 F.3d 1022, 1031 (Fed. Cir. 2002). We find that the term “substantially” was used in just such a manner in the claims of the patents-in-suit: “substantially uniform wall thickness” denotes a wall thickness with approximate uniformity.

It should also be noted that such words of approximation as contemplated in the foregoing clearly limits the scope of claims such as saying ‘generally parallel’ such that the adverb ‘generally’ does not broaden the meaning of parallel. Accordingly, it is well settled that such words of approximation as contemplated in the foregoing (e.g., like the phrase ‘generally parallel’) envisions some amount of deviation from perfection (e.g., not exactly parallel), and that such words of approximation as contemplated in the foregoing are descriptive terms commonly used in patent claims to avoid a strict numerical boundary to the specified parameter. To the extent that the plain language of the claims relying on such words of approximation as contemplated in the foregoing are clear and uncontradicted by anything in the written description herein or the figures thereof, it is improper to rely upon the present written description, the figures, or the prosecution history to add limitations to any of the claim of the present invention with respect to such words of approximation as contemplated in the foregoing. That is, under such circumstances, relying on the written description and prosecution history to reject the ordinary and customary meanings of the words themselves is impermissible. See, for example, Liquid Dynamics Corp. v. Vaughan Co., 355 F.3d 1361, 69 USPQ2d 1595, 1600-01 (Fed. Cir. 2004). The plain language of phrase 2 requires a “substantial helical flow.” The term “substantial” is a meaningful modifier implying “approximate,” rather than “perfect.” In Cordis Corp. v. Medtronic AVE, Inc., 339 F.3d 1352, 1361 (Fed. Cir. 2003), the district court imposed a precise numeric constraint on the term “substantially uniform thickness.” We noted that the proper interpretation of this term was “of largely or approximately uniform thickness” unless something in the prosecution history imposed the “clear and unmistakable disclaimer” needed for narrowing beyond this simple-language interpretation. Id. In Anchor Wall Systems v. Rockwood Retaining Walls, Inc., 340 F.3d 1298, 1311 (Fed. Cir. 2003)” Id. at 1311. Similarly, the plain language of claim 1 requires neither a perfectly helical flow nor a flow that returns precisely to the center after one rotation (a limitation that arises only as a logical consequence of requiring a perfectly helical flow).

The reader should appreciate that case law generally recognizes a dual ordinary meaning of such words of approximation, as contemplated in the foregoing, as connoting a term of approximation or a term of magnitude; e.g., see Deering Precision Instruments, L.L.C. v. Vector Distrib. Sys., Inc., 347 F.3d 1314, 68 USPQ2d 1716, 1721 (Fed. Cir. 2003), cert. denied, 124 S. Ct. 1426 (2004) where the court was asked to construe the meaning of the term “substantially” in a patent claim. Also see Epcon, 279 F.3d at 1031 (“The phrase ‘substantially constant’ denotes language of approximation, while the phrase ‘substantially below’ signifies language of magnitude, i.e., not insubstantial.”). Also, see, e.g., Epcon Gas Sys., Inc. v. Bauer Compressors, Inc., 279 F.3d 1022 (Fed. Cir. 2002) (construing the terms “substantially constant” and “substantially below”); Zodiac Pool Care, Inc. v. Hoffinger Indus., Inc., 206 F.3d 1408 (Fed. Cir. 2000) (construing the term “substantially inward”); York Prods., Inc. v. Cent. Tractor Farm & Family Ctr., 99 F.3d 1568 (Fed. Cir. 1996) (construing the term “substantially the entire height thereof”); Tex. Instruments Inc. v. Cypress Semiconductor Corp., 90 F.3d 1558 (Fed. Cir. 1996) (construing the term “substantially in the common plane”). In conducting their analysis, the court instructed to begin with the ordinary meaning of the claim terms to one of ordinary skill in the art. Prima Tek, 318 F.3d at 1148. Reference to dictionaries and our cases indicates that the term “substantially” has numerous ordinary meanings. As the district court stated, “substantially” can mean “significantly” or “considerably.” The term “substantially” can also mean “largely” or “essentially.” Webster's New 20th Century Dictionary 1817 (1983).

Words of approximation, as contemplated in the foregoing, may also be used in phrases establishing approximate ranges or limits, where the end points are inclusive and approximate, not perfect; e.g., see AK Steel Corp. v. Sollac, 344 F.3d 1234, 68 USPQ2d 1280, 1285 (Fed. Cir. 2003) where it where the court said [W]e conclude that the ordinary meaning of the phrase “up to about 10%” includes the “about 10%” endpoint. As pointed out by AK Steel, when an object of the preposition “up to” is nonnumeric, the most natural meaning is to exclude the object (e.g., painting the wall up to the door). On the other hand, as pointed out by Sollac, when the object is a numerical limit, the normal meaning is to include that upper numerical limit (e.g., counting up to ten, seating capacity for up to seven passengers). Because we have here a numerical limit—“about 10%”—the ordinary meaning is that that endpoint is included.

In the present specification and claims, a goal of employment of such words of approximation, as contemplated in the foregoing, is to avoid a strict numerical boundary to the modified specified parameter, as sanctioned by Pall Corp. v. Micron Separations, Inc., 66 F.3d 1211, 1217, 36 USPQ2d 1225, 1229 (Fed. Cir. 1995) where it states “It is well established that when the term “substantially” serves reasonably to describe the subject matter so that its scope would be understood by persons in the field of the invention, and to distinguish the claimed subject matter from the prior art, it is not indefinite.” Likewise see Verve LLC v. Crane Cams Inc., 311 F.3d 1116, 65 USPQ2d 1051, 1054 (Fed. Cir. 2002). Expressions such as “substantially” are used in patent documents when warranted by the nature of the invention, in order to accommodate the minor variations that may be appropriate to secure the invention. Such usage may well satisfy the charge to “particularly point out and distinctly claim” the invention, 35 U.S.C. § 112, and indeed may be necessary in order to provide the inventor with the benefit of his invention. In Andrew Corp. v. Gabriel Elecs. Inc., 847 F.2d 819, 821-22, 6 USPQ2d 2010, 2013 (Fed. Cir. 1988) the court explained that usages such as “substantially equal” and “closely approximate” may serve to describe the invention with precision appropriate to the technology and without intruding on the prior art. The court again explained in Ecolab Inc. v. Envirochem, Inc., 264 F.3d 1358, 1367, 60 USPQ2d 1173, 1179 (Fed. Cir. 2001) that “like the term ‘about,’ the term ‘substantially’ is a descriptive term commonly used in patent claims to ‘avoid a strict numerical boundary to the specified parameter, see Ecolab Inc. v. Envirochem Inc., 264 F.3d 1358, 60 USPQ2d 1173, 1179 (Fed. Cir. 2001) where the court found that the use of the term “substantially” to modify the term “uniform” does not render this phrase so unclear such that there is no means by which to ascertain the claim scope.

Similarly, other courts have noted that like the term “about,” the term “substantially” is a descriptive term commonly used in patent claims to “avoid a strict numerical boundary to the specified parameter.”; e.g., see Pall Corp. v. Micron Seps., 66 F.3d 1211, 1217, 36 USPQ2d 1225, 1229 (Fed. Cir. 1995); see, e.g., Andrew Corp. v. Gabriel Elecs. Inc., 847 F.2d 819, 821-22, 6 USPQ2d 2010, 2013 (Fed. Cir. 1988) (noting that terms such as “approach each other,” “close to,” “substantially equal,” and “closely approximate” are ubiquitously used in patent claims and that such usages, when serving reasonably to describe the claimed subject matter to those of skill in the field of the invention, and to distinguish the claimed subject matter from the prior art, have been accepted in patent examination and upheld by the courts). In this case, “substantially” avoids the strict 100% nonuniformity boundary.

Indeed, the foregoing sanctioning of such words of approximation, as contemplated in the foregoing, has been established as early as 1939, see Ex parte Mallory, 52 USPQ 297, 297 (Pat. Off. Bd. App. 1941) where, for example, the court said “the claims specify that the film is “substantially” eliminated and for the intended purpose, it is believed that the slight portion of the film which may remain is negligible. We are of the view, therefore, that the claims may be regarded as sufficiently accurate.” Similarly, In re Hutchison, 104 F.2d 829, 42 USPQ 90, 93 (C.C.P.A. 1939) the court said “It is realized that “substantial distance” is a relative and somewhat indefinite term, or phrase, but terms and phrases of this character are not uncommon in patents in cases where, according to the art involved, the meaning can be determined with reasonable clearness.”

Hence, for at least the forgoing reason, Applicants submit that it is improper for any examiner to hold as indefinite any claims of the present patent that employ any words of approximation.

Unless defined otherwise, all technical and scientific terms used herein have the same meanings as commonly understood by one of ordinary skill in the art to which this invention belongs. Preferred methods, techniques, devices, and materials are described, although any methods, techniques, devices, or materials similar or equivalent to those described herein may be used in the practice or testing of the present invention. Structures described herein are to be understood also to refer to functional equivalents of such structures. The present invention will be described in detail below with reference to embodiments thereof as illustrated in the accompanying drawings.

References to a “device,” an “apparatus,” a “system,” etc., in the preamble of a claim should be construed broadly to mean “any structure meeting the claim terms” exempt for any specific structure(s)/type(s) that has/(have) been explicitly disavowed or excluded or admitted/implied as prior art in the present specification or incapable of enabling an object/aspect/goal of the invention. Furthermore, where the present specification discloses an object, aspect, function, goal, result, or advantage of the invention that a specific prior art structure and/or method step is similarly capable of performing yet in a very different way, the present invention disclosure is intended to and shall also implicitly include and cover additional corresponding alternative embodiments that are otherwise identical to that explicitly disclosed except that they exclude such prior art structure(s)/step(s), and shall accordingly be deemed as providing sufficient disclosure to support a corresponding negative limitation in a claim claiming such alternative embodiment(s), which exclude such very different prior art structure(s)/step(s) way(s).

From reading the present disclosure, other variations and modifications will be apparent to persons skilled in the art. Such variations and modifications may involve equivalent and other features which are already known in the art, and which may be used instead of or in addition to features already described herein.

Although Claims have been formulated in this Application to particular combinations of features, it should be understood that the scope of the disclosure of the present invention also includes any novel feature or any novel combination of features disclosed herein either explicitly or implicitly or any generalization thereof, whether or not it relates to the same invention as presently claimed in any Claim and whether or not it mitigates any or all of the same technical problems as does the present invention.

Features which are described in the context of separate embodiments may also be provided in combination in a single embodiment. Conversely, various features which are, for brevity, described in the context of a single embodiment, may also be provided separately or in any suitable subcombination. The Applicants hereby give notice that new Claims may be formulated to such features and/or combinations of such features during the prosecution of the present Application or of any further Application derived therefrom.

References to “one embodiment,” “an embodiment,” “example embodiment,” “various embodiments,” “some embodiments,” “embodiments of the invention,” etc., may indicate that the embodiment(s) of the invention so described may include a particular feature, structure, or characteristic, but not every possible embodiment of the invention necessarily includes the particular feature, structure, or characteristic. Further, repeated use of the phrase “in one embodiment,” or “in an exemplary embodiment,” “an embodiment,” do not necessarily refer to the same embodiment, although they may. Moreover, any use of phrases like “embodiments” in connection with “the invention” are never meant to characterize that all embodiments of the invention must include the particular feature, structure, or characteristic, and should instead be understood to mean “at least some embodiments of the invention” include the stated particular feature, structure, or characteristic.

References to “user”, or any similar term, as used herein, may mean a human or non-human user thereof. Moreover, “user”, or any similar term, as used herein, unless expressly stipulated otherwise, is contemplated to mean users at any stage of the usage process, to include, without limitation, direct user(s), intermediate user(s), indirect user(s), and end user(s). The meaning of “user”, or any similar term, as used herein, should not be otherwise inferred or induced by any pattern(s) of description, embodiments, examples, or referenced prior-art that may (or may not) be provided in the present patent.

References to “end user”, or any similar term, as used herein, are generally intended to mean late stage user(s) as opposed to early stage user(s). Hence, it is contemplated that there may be a multiplicity of different types of “end user” near the end stage of the usage process. Where applicable, especially with respect to distribution channels of embodiments of the invention comprising consumed retail products/services thereof (as opposed to sellers/vendors or Original Equipment Manufacturers), examples of an “end user” may include, without limitation, a “consumer”, “buyer”, “customer”, “purchaser”, “shopper”, “enjoyer”, “viewer”, or individual person or non-human thing benefiting in any way, directly or indirectly, from use of or interaction, with some aspect of the present invention.

In some situations, some embodiments of the present invention may provide beneficial usage to more than one stage or type of usage in the foregoing usage process. In such cases where multiple embodiments targeting various stages of the usage process are described, references to “end user”, or any similar term, as used therein, are generally intended to not include the user that is the furthest removed, in the foregoing usage process, from the final user therein of an embodiment of the present invention.

Where applicable, especially with respect to retail distribution channels of embodiments of the invention, intermediate user(s) may include, without limitation, any individual person or non-human thing benefiting in any way, directly or indirectly, from use of, or interaction with, some aspect of the present invention with respect to selling, vending, Original Equipment Manufacturing, marketing, merchandising, distributing, service providing, and the like thereof.

References to “person”, “individual”, “human”, “a party”, “animal”, “creature”, or any similar term, as used herein, even if the context or particular embodiment implies living user, maker, or participant, it should be understood that such characterizations are sole by way of example, and not limitation, in that it is contemplated that any such usage, making, or participation by a living entity in connection with making, using, and/or participating, in any way, with embodiments of the present invention may be substituted by such similar performed by a suitably configured non-living entity, to include, without limitation, automated machines, robots, humanoids, computational systems, information processing systems, artificially intelligent systems, and the like. It is further contemplated that those skilled in the art will readily recognize the practical situations where such living makers, users, and/or participants with embodiments of the present invention may be in whole, or in part, replaced with such non-living makers, users, and/or participants with embodiments of the present invention. Likewise, when those skilled in the art identify such practical situations where such living makers, users, and/or participants with embodiments of the present invention may be in whole, or in part, replaced with such non-living makers, it will be readily apparent in light of the teachings of the present invention how to adapt the described embodiments to be suitable for such non-living makers, users, and/or participants with embodiments of the present invention. Thus, the invention is thus to also cover all such modifications, equivalents, and alternatives falling within the spirit and scope of such adaptations and modifications, at least in part, for such non-living entities.

Headings provided herein are for convenience and are not to be taken as limiting the disclosure in any way.

The enumerated listing of items does not imply that any or all of the items are mutually exclusive, unless expressly specified otherwise.

It is understood that the use of specific component, device and/or parameter names are for example only and not meant to imply any limitations on the invention. The invention may thus be implemented with different nomenclature/terminology utilized to describe the mechanisms/units/structures/components/devices/parameters herein, without limitation. Each term utilized herein is to be given its broadest interpretation given the context in which that term is utilized.

Terminology. The following paragraphs provide definitions and/or context for terms found in this disclosure (including the appended claims):

“Comprising.” This term is open-ended. As used in the appended claims, this term does not foreclose additional structure or steps. Consider a claim that recites: “A memory controller comprising a system cache . . . .” Such a claim does not foreclose the memory controller from including additional components (e.g., a memory channel unit, a switch).

“Configured To.” Various units, circuits, or other components may be described or claimed as “configured to” perform a task or tasks. In such contexts, “configured to” or “operable for” is used to connote structure by indicating that the mechanisms/units/circuits/components include structure (e.g., circuitry and/or mechanisms) that performs the task or tasks during operation. As such, the mechanisms/unit/circuit/component can be said to be configured to (or be operable) for perform(ing) the task even when the specified mechanisms/unit/circuit/component is not currently operational (e.g., is not on). The mechanisms/units/circuits/components used with the “configured to” or “operable for” language include hardware—for example, mechanisms, structures, electronics, circuits, memory storing program instructions executable to implement the operation, etc. Reciting that a mechanism/unit/circuit/component is “configured to” or “operable for” perform(ing) one or more tasks is expressly intended not to invoke 35 U.S.C. .sctn.112, sixth paragraph, for that mechanism/unit/circuit/component. “Configured to” may also include adapting a manufacturing process to fabricate devices or components that are adapted to implement or perform one or more tasks.

“Based On.” As used herein, this term is used to describe one or more factors that affect a determination. This term does not foreclose additional factors that may affect a determination. That is, a determination may be solely based on those factors or based, at least in part, on those factors. Consider the phrase “determine A based on B.” While B may be a factor that affects the determination of A, such a phrase does not foreclose the determination of A from also being based on C. In other instances, A may be determined based solely on B.

The terms “a”, “an” and “the” mean “one or more”, unless expressly specified otherwise.

Unless otherwise indicated, all numbers expressing conditions, concentrations, dimensions, and so forth used in the specification and claims are to be understood as being modified in all instances by the term “about.” Accordingly, unless indicated to the contrary, the numerical parameters set forth in the following specification and attached claims are approximations that may vary depending at least upon a specific analytical technique.

The term “comprising,” which is synonymous with “including,” “containing,” or “characterized by” is inclusive or open-ended and does not exclude additional, unrecited elements or method steps. “Comprising” is a term of art used in claim language which means that the named claim elements are essential, but other claim elements may be added and still form a construct within the scope of the claim.

As used herein, the phase “consisting of” excludes any element, step, or ingredient not specified in the claim. When the phrase “consists of” (or variations thereof) appears in a clause of the body of a claim, rather than immediately following the preamble, it limits only the element set forth in that clause; other elements are not excluded from the claim as a whole. As used herein, the phase “consisting essentially of” and “consisting of” limits the scope of a claim to the specified elements or method steps, plus those that do not materially affect the basis and novel characteristic(s) of the claimed subject matter (see Norian Corp. v Stryker Corp., 363 F.3d 1321, 1331-32, 70 USPQ2d 1508, Fed. Cir. 2004). Moreover, for any claim of the present invention which claims an embodiment “consisting essentially of” or “consisting of” a certain set of elements of any herein described embodiment it shall be understood as obvious by those skilled in the art that the present invention also covers all possible varying scope variants of any described embodiment(s) that are each exclusively (i.e., “consisting essentially of”) functional subsets or functional combination thereof such that each of these plurality of exclusive varying scope variants each consists essentially of any functional subset(s) and/or functional combination(s) of any set of elements of any described embodiment(s) to the exclusion of any others not set forth therein. That is, it is contemplated that it will be obvious to those skilled how to create a multiplicity of alternate embodiments of the present invention that simply consisting essentially of a certain functional combination of elements of any described embodiment(s) to the exclusion of any others not set forth therein, and the invention thus covers all such exclusive embodiments as if they were each described herein.

With respect to the terms “comprising,” “consisting of,” and “consisting essentially of,” where one of these three terms is used herein, the disclosed and claimed subject matter may include the use of either of the other two terms. Thus in some embodiments not otherwise explicitly recited, any instance of “comprising” may be replaced by “consisting of” or, alternatively, by “consisting essentially of”, and thus, for the purposes of claim support and construction for “consisting of” format claims, such replacements operate to create yet other alternative embodiments “consisting essentially of” only the elements recited in the original “comprising” embodiment to the exclusion of all other elements.

Moreover, any claim limitation phrased in functional limitation terms covered by 35 USC § 112(6) (post AIA 112(f)) which has a preamble invoking the closed terms “consisting of,” or “consisting essentially of,” should be understood to mean that the corresponding structure(s) disclosed herein define the exact metes and bounds of what the so claimed invention embodiment(s) consists of, or consisting essentially of, to the exclusion of any other elements which do not materially affect the intended purpose of the so claimed embodiment(s).

Devices or system modules that are in at least general communication with each other need not be in continuous communication with each other, unless expressly specified otherwise. In addition, devices or system modules that are in at least general communication with each other may communicate directly or indirectly through one or more intermediaries. Moreover, it is understood that any system components described or named in any embodiment or claimed herein may be grouped or sub-grouped (and accordingly implicitly renamed) in any combination or sub-combination as those skilled in the art can imagine as suitable for the particular application, and still be within the scope and spirit of the claimed embodiments of the present invention. For an example of what this means, if the invention was a controller of a motor and a valve and the embodiments and claims articulated those components as being separately grouped and connected, applying the foregoing would mean that such an invention and claims would also implicitly cover the valve being grouped inside the motor and the controller being a remote controller with no direct physical connection to the motor or internalized valve, as such the claimed invention is contemplated to cover all ways of grouping and/or adding of intermediate components or systems that still substantially achieve the intended result of the invention.

A description of an embodiment with several components in communication with each other does not imply that all such components are required. On the contrary a variety of optional components are described to illustrate the wide variety of possible embodiments of the present invention.

As is well known to those skilled in the art many careful considerations and compromises typically must be made when designing for the optimal manufacture of a commercial implementation any system, and in particular, the embodiments of the present invention. A commercial implementation in accordance with the spirit and teachings of the present invention may configured according to the needs of the particular application, whereby any aspect(s), feature(s), function(s), result(s), component(s), approach(es), or step(s) of the teachings related to any described embodiment of the present invention may be suitably omitted, included, adapted, mixed and matched, or improved and/or optimized by those skilled in the art, using their average skills and known techniques, to achieve the desired implementation that addresses the needs of the particular application.

A “computer” may refer to one or more apparatus and/or one or more systems that are capable of accepting a structured input, processing the structured input according to prescribed rules, and producing results of the processing as output. Examples of a computer may include: a computer; a stationary and/or portable computer; a computer having a single processor, multiple processors, or multi-core processors, which may operate in parallel and/or not in parallel; a general purpose computer; a supercomputer; a mainframe; a super mini-computer; a mini-computer; a workstation; a micro-computer; a server; a client; an interactive television; a web appliance; a telecommunications device with internet access; a hybrid combination of a computer and an interactive television; a portable computer; a tablet personal computer (PC); a personal digital assistant (PDA); a portable telephone; application-specific hardware to emulate a computer and/or software, such as, for example, a digital signal processor (DSP), a field-programmable gate array (FPGA), an application specific integrated circuit (ASIC), an application specific instruction-set processor (ASIP), a chip, chips, a system on a chip, or a chip set; a data acquisition device; an optical computer; a quantum computer; a biological computer; and generally, an apparatus that may accept data, process data according to one or more stored software programs, generate results, and typically include input, output, storage, arithmetic, logic, and control units.

Those of skill in the art will appreciate that where appropriate, some embodiments of the disclosure may be practiced in network computing environments with many types of computer system configurations, including personal computers, hand-held devices, multi-processor systems, microprocessor-based or programmable consumer electronics, network PCs, minicomputers, mainframe computers, and the like. Where appropriate, embodiments may also be practiced in distributed computing environments where tasks are performed by local and remote processing devices that are linked (either by hardwired links, wireless links, or by a combination thereof) through a communications network. In a distributed computing environment, program modules may be located in both local and remote memory storage devices.

“Software” may refer to prescribed rules to operate a computer. Examples of software may include: code segments in one or more computer-readable languages; graphical and or/textual instructions; applets; pre-compiled code; interpreted code; compiled code; and computer programs.

The example embodiments described herein can be implemented in an operating environment comprising computer-executable instructions (e.g., software) installed on a computer, in hardware, or in a combination of software and hardware. The computer-executable instructions can be written in a computer programming language or can be embodied in firmware logic. If written in a programming language conforming to a recognized standard, such instructions can be executed on a variety of hardware platforms and for interfaces to a variety of operating systems. Although not limited thereto, computer software program code for carrying out operations for aspects of the present invention can be written in any combination of one or more suitable programming languages, including an object oriented programming languages and/or conventional procedural programming languages, and/or programming languages such as, for example, Hyper text Markup Language (HTML), Dynamic HTML, Extensible Markup Language (XML), Extensible Stylesheet Language (XSL), Document Style Semantics and Specification Language (DSSSL), Cascading Style Sheets (CSS), Synchronized Multimedia Integration Language (SMIL), Wireless Markup Language (WML), Java.™, Jini.™, C, C++, Smalltalk, Perl, UNIX Shell, Visual Basic or Visual Basic Script, Virtual Reality Markup Language (VRML), ColdFusion.™ or other compilers, assemblers, interpreters or other computer languages or platforms.

Computer program code for carrying out operations for aspects of the present invention may be written in any combination of one or more programming languages, including an object oriented programming language such as Java, Smalltalk, C++ or the like and conventional procedural programming languages, such as the “C” programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

A network is a collection of links and nodes (e.g., multiple computers and/or other devices connected together) arranged so that information may be passed from one part of the network to another over multiple links and through various nodes. Examples of networks include the Internet, the public switched telephone network, the global Telex network, computer networks (e.g., an intranet, an extranet, a local-area network, or a wide-area network), wired networks, and wireless networks.

The Internet is a worldwide network of computers and computer networks arranged to allow the easy and robust exchange of information between computer users. Hundreds of millions of people around the world have access to computers connected to the Internet via Internet Service Providers (ISPs). Content providers (e.g., web site owners or operators) place multimedia information (e.g., text, graphics, audio, video, animation, and other forms of data) at specific locations on the Internet referred to as webpages. Websites comprise a collection of connected, or otherwise related, webpages. The combination of all the websites and their corresponding webpages on the Internet is generally known as the World Wide Web (WWW) or simply the Web.

Aspects of the present invention are described below with reference to flowchart illustrations and/or block diagrams of methods, apparatus (systems) and computer program products according to embodiments of the invention. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

The flowchart and block diagrams in the figures illustrate the architecture, functionality, and operation of possible implementations of systems, methods and computer program products according to various embodiments. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

These computer program instructions may also be stored in a computer readable medium that can direct a computer, other programmable data processing apparatus, or other devices to function in a particular manner, such that the instructions stored in the computer readable medium produce an article of manufacture including instructions which implement the function/act specified in the flowchart and/or block diagram block or blocks.

Further, although process steps, method steps, algorithms or the like may be described in a sequential order, such processes, methods and algorithms may be configured to work in alternate orders. In other words, any sequence or order of steps that may be described does not necessarily indicate a requirement that the steps be performed in that order. The steps of processes described herein may be performed in any order practical. Further, some steps may be performed simultaneously.

It will be readily apparent that the various methods and algorithms described herein may be implemented by, e.g., appropriately programmed general purpose computers and computing devices. Typically a processor (e.g., a microprocessor) will receive instructions from a memory or like device, and execute those instructions, thereby performing a process defined by those instructions. Further, programs that implement such methods and algorithms may be stored and transmitted using a variety of known media.

When a single device or article is described herein, it will be readily apparent that more than one device/article (whether or not they cooperate) may be used in place of a single device/article. Similarly, where more than one device or article is described herein (whether or not they cooperate), it will be readily apparent that a single device/article may be used in place of the more than one device or article.

The functionality and/or the features of a device may be alternatively embodied by one or more other devices which are not explicitly described as having such functionality/features. Thus, other embodiments of the present invention need not include the device itself.

The term “computer-readable medium” as used herein refers to any medium that participates in providing data (e.g., instructions) which may be read by a computer, a processor or a like device. Such a medium may take many forms, including but not limited to, non-volatile media, volatile media, and transmission media. Non-volatile media include, for example, optical or magnetic disks and other persistent memory. Volatile media include dynamic random access memory (DRAM), which typically constitutes the main memory. Transmission media include coaxial cables, copper wire and fiber optics, including the wires that comprise a system bus coupled to the processor. Transmission media may include or convey acoustic waves, light waves and electromagnetic emissions, such as those generated during radio frequency (RF) and infrared (IR) data communications. Common forms of computer-readable media include, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, an EPROM, a FLASH-EEPROM, removable media, flash memory, a “memory stick”, any other memory chip or cartridge, a carrier wave as described hereinafter, or any other medium from which a computer can read.

Various forms of computer readable media may be involved in carrying sequences of instructions to a processor. For example, sequences of instruction (i) may be delivered from RAM to a processor, (ii) may be carried over a wireless transmission medium, and/or (iii) may be formatted according to numerous formats, standards or protocols, such as Bluetooth, TDMA, CDMA, 3G.

Where databases are described, it will be understood by one of ordinary skill in the art that (i) alternative database structures to those described may be readily employed, (ii) other memory structures besides databases may be readily employed. Any schematic illustrations and accompanying descriptions of any sample databases presented herein are exemplary arrangements for stored representations of information. Any number of other arrangements may be employed besides those suggested by the tables shown. Similarly, any illustrated entries of the databases represent exemplary information only; those skilled in the art will understand that the number and content of the entries can be different from those illustrated herein. Further, despite any depiction of the databases as tables, an object-based model could be used to store and manipulate the data types of the present invention and likewise, object methods or behaviors can be used to implement the processes of the present invention.

A “computer system” may refer to a system having one or more computers, where each computer may include a computer-readable medium embodying software to operate the computer or one or more of its components. Examples of a computer system may include: a distributed computer system for processing information via computer systems linked by a network; two or more computer systems connected together via a network for transmitting and/or receiving information between the computer systems; a computer system including two or more processors within a single computer; and one or more apparatuses and/or one or more systems that may accept data, may process data in accordance with one or more stored software programs, may generate results, and typically may include input, output, storage, arithmetic, logic, and control units.

A “network” may refer to a number of computers and associated devices that may be connected by communication facilities. A network may involve permanent connections such as cables or temporary connections such as those made through telephone or other communication links. A network may further include hard-wired connections (e.g., coaxial cable, twisted pair, optical fiber, waveguides, etc.) and/or wireless connections (e.g., radio frequency waveforms, free-space optical waveforms, acoustic waveforms, etc.). Examples of a network may include: an internet, such as the Internet; an intranet; a local area network (LAN); a wide area network (WAN); and a combination of networks, such as an internet and an intranet.

As used herein, the “client-side” application should be broadly construed to refer to an application, a page associated with that application, or some other resource or function invoked by a client-side request to the application. A “browser” as used herein is not intended to refer to any specific browser (e.g., Internet Explorer, Safari, FireFox, or the like), but should be broadly construed to refer to any client-side rendering engine that can access and display Internet-accessible resources. A “rich” client typically refers to a non-HTTP based client-side application, such as an SSH or CFIS client. Further, while typically the client-server interactions occur using HTTP, this is not a limitation either. The client server interaction may be formatted to conform to the Simple Object Access Protocol (SOAP) and travel over HTTP (over the public Internet), FTP, or any other reliable transport mechanism (such as IBM.® MQSeries.® technologies and CORBA, for transport over an enterprise intranet) may be used. Any application or functionality described herein may be implemented as native code, by providing hooks into another application, by facilitating use of the mechanism as a plug-in, by linking to the mechanism, and the like.

Exemplary networks may operate with any of a number of protocols, such as Internet protocol (IP), asynchronous transfer mode (ATM), and/or synchronous optical network (SONET), user datagram protocol (UDP), IEEE 802.x, etc.

Embodiments of the present invention may include apparatuses for performing the operations disclosed herein. An apparatus may be specially constructed for the desired purposes, or it may comprise a general-purpose device selectively activated or reconfigured by a program stored in the device.

Embodiments of the invention may also be implemented in one or a combination of hardware, firmware, and software. They may be implemented as instructions stored on a machine-readable medium, which may be read and executed by a computing platform to perform the operations described herein.

More specifically, as will be appreciated by one skilled in the art, aspects of the present invention may be embodied as a system, method or computer program product. Accordingly, aspects of the present invention may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects of the present invention may take the form of a computer program product embodied in one or more computer readable medium(s) having computer readable program code embodied thereon.

In the following description and claims, the terms “computer program medium” and “computer readable medium” may be used to generally refer to media such as, but not limited to, removable storage drives, a hard disk installed in hard disk drive, and the like. These computer program products may provide software to a computer system. Embodiments of the invention may be directed to such computer program products.

An algorithm is here, and generally, considered to be a self-consistent sequence of acts or operations leading to a desired result. These include physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers or the like. It should be understood, however, that all of these and similar terms are to be associated with the appropriate physical quantities and are merely convenient labels applied to these quantities.

Unless specifically stated otherwise, and as may be apparent from the following description and claims, it should be appreciated that throughout the specification descriptions utilizing terms such as “processing,” “computing,” “calculating,” “determining,” or the like, refer to the action and/or processes of a computer or computing system, or similar electronic computing device, that manipulate and/or transform data represented as physical, such as electronic, quantities within the computing system's registers and/or memories into other data similarly represented as physical quantities within the computing system's memories, registers or other such information storage, transmission or display devices.

Additionally, the phrase “configured to” or “operable for” can include generic structure (e.g., generic circuitry) that is manipulated by software and/or firmware (e.g., an FPGA or a general-purpose processor executing software) to operate in a manner that is capable of performing the task(s) at issue. “Configured to” may also include adapting a manufacturing process (e.g., a semiconductor fabrication facility) to fabricate devices (e.g., integrated circuits) that are adapted to implement or perform one or more tasks.

In a similar manner, the term “processor” may refer to any device or portion of a device that processes electronic data from registers and/or memory to transform that electronic data into other electronic data that may be stored in registers and/or memory. A “computing platform” may comprise one or more processors.

Embodiments within the scope of the present disclosure may also include tangible and/or non-transitory computer-readable storage media for carrying or having computer-executable instructions or data structures stored thereon. Such non-transitory computer-readable storage media can be any available media that can be accessed by a general purpose or special purpose computer, including the functional design of any special purpose processor as discussed above. By way of example, and not limitation, such non-transitory computer-readable media can include RAM, ROM, EEPROM, CD-ROM or other optical disk storage, magnetic disk storage or other magnetic storage devices, or any other medium which can be used to carry or store desired program code means in the form of computer-executable instructions, data structures, or processor chip design. When information is transferred or provided over a network or another communications connection (either hardwired, wireless, or combination thereof) to a computer, the computer properly views the connection as a computer-readable medium. Thus, any such connection is properly termed a computer-readable medium. Combinations of the above should also be included within the scope of the computer-readable media.

While a non-transitory computer readable medium includes, but is not limited to, a hard drive, compact disc, flash memory, volatile memory, random access memory, magnetic memory, optical memory, semiconductor based memory, phase change memory, optical memory, periodically refreshed memory, and the like; the non-transitory computer readable medium, however, does not include a pure transitory signal per se; i.e., where the medium itself is transitory.

It is to be understood that any exact measurements/dimensions or particular construction materials indicated herein are solely provided as examples of suitable configurations and are not intended to be limiting in any way. Depending on the needs of the particular application, those skilled in the art will readily recognize, in light of the following teachings, a multiplicity of suitable alternative implementation details.

In one embodiment the present invention may provide an improved passive RFID tag where inorganic materials are used to build the tag. Furthermore, these RFID tags may be fully printed on a metal foil substrate, which may also make them ideal for large scale production. Furthermore still, micro-fabrication steps may also be improved where pre-surface treatment and photonics curing may be enhanced. Furthermore still, the RFID tag may be flexible which would greatly increase the number of possible applications and improve durability. Furthermore still, in alternative embodiment the RFID tag may be flexible only partly in order to shape it like a shape of a product to be tracked. Furthermore still, the RFID tag may be relatively more resistant to high temperatures and harsh environments. Producing RFID tags with inorganic materials may provide solutions to improve stability, operate at higher frequencies, and allow it to be readable at long distances. Furthermore still, a cost to produce these RFID tags has been greatly reduced leaving them comparable to the price of using barcodes and other labels. Furthermore still, a fully printed inorganic RFID tag may be an electronic device that has the ability to store and/or process data/logic and may be interfaced with using radio frequency communication. One major function of an RFID tag may be to provide object traceability and interfacing abilities to any component that it is placed on. The RFID tag which may be built to withstand high temperatures or harsh environments, may be suitable for tagging components in industries including but not limited to an automotive supplier industry. In this kind of environment, a tag may keep track of information about a component as it moves through a manufacturing line, helping to reduce manufacturing delays. A digital logic portion of a tag may be fully printed and may contain components including but not limited to a clock generator, 3-bit binary counter, line selector, multiplexor, ROM, output register, data encoding, anti-collision protocol, and/or antennae. Every single component on an RFID tag may be printed and made from scratch, there may be nothing pre-made. A tag may be encapsulated using a solution-based processes. A solution based process for encapsulation would make it compatible with the printing process and minimize processing time and costs. Other types of encapsulation include molding, glob-topping, potting, and under filling which may not be well suited for this application. In an embodiment all components of an RFID tag may be made from scratch and nothing may be pre-made. A RFID tag may furthermore be encapsulated using a solution-based processes and an active layer of each transistor may be made with solution processed inorganic ink. A substrate for a fully printed passive RFID tag may be made of materials including but not limited to a relatively thin metal foil. Other types of substrates may include, but not limited to, glass based substrates, polymer based substrates, silicon based substrates, ceramic based substrates or composite materials. Furthermore still, in alternative embodiment the RFID tag may be made from improved more flexible and/or more customized and/or more computationally complex.

When designing a structure for a RFID tag, there may be a large plurality of factors that may significantly affect performance and applicability. Attempting to improve one factor may negatively affect another factor, so understanding and considering every element's behavior may be a key aspect in improving RFID tags thoroughly. Areas of consideration may include but are not limited to a thermal budget, a surface characterization, an ink compatibility, an energy band alignment, and a breakdown prevention. When considering a thermal budget, each layer may have its own temperature requirements and how long it may be annealed for. A stack may become problematic because bottom layers may be annealed again each time a new layer may be added. A film may break down if annealed for too long or too high of temperature. In an exemplary embodiment, some processing techniques to generally avoid exceeding a thermal budget on each layer may include but may not be limited to a soft bake where this technique may be useful when layering multiple coatings of a same ink. Other methods may include photonic curing, rapid thermal annealing, or laser annealing. A soft bake may be performed at a lower temperature than a required annealing temperature and for a shorter amount of time. One possible goal may be to remove a solvent from ink and induce metal oxide network formation so a next coating may not dissolve a previous one. In an exemplary embodiment when building a gate insulator, it may be beneficial to layer multiple coatings of a same ink. For this example we may use aluminum oxide. Other alternatives for gate insulator material include lanthanum oxide, hafnium oxide, silicon oxide, zirconium oxide, silicon oxynitride, tantalum oxide, silicon nitride, yttrium oxide, titanium oxide, germanium oxide, binary and ternary based oxides, and polymer based materials. A precursor for aluminum oxide may be annealed at 250° C. for 1 hour. A soft bake technique may anneal each layer for 10 minutes at 200° C. Another technique to avoid exceeding a thermal budget on each layer may be a soft anneal where this technique may be useful when layering different ink types. A soft anneal may be performed at a required temperature to drive a desired reaction to occur, but may not proceed to completion. Reactions that may be induced during soft anneal include, but not limited to, solvent evaporation, hydrolysis, condensation, initial metal oxide network formation, and cross linking. In a previous aluminum oxide example, a soft anneal may be performed at 250° C. for 30 minutes. Another technique to avoid exceeding a thermal budget on each layer may be photonic curing, where this technique may rely on a high-powered xenon lamp to deliver large amounts of energy in a relatively very short amount of time. One possible goal from plural possible goals may be to heat up only a top layer in a stack without affecting everything below it. This technique may be useful for annealing a semiconducting layer in a transistor and also interconnects. Commercially available photonic curing equipment may allow for tuning of processing conditions to meet needs of a material being annealed. For metal oxide precursors used in an RFID tag device, following processing conditions may generally result in functioning devices. During an exemplary procedure, a number of flashes may range between 1-35, radiant energy delivered may range between 5-45 J/cm2, a pulse length may range between 500-50,000 microseconds, output spectrum may range between 200-1500 nanometers. These ranges are typical ranges used in the industry. Using values outside these ranges may still result in functional films and devices, but may require adjustments in other processing steps. A photonic curing technique may be followed by a thermal annealing step (depending on a thermal budget of a stack) to improve a performance of a target layer. In an exemplary embodiment a processing condition for an indium gallium zinc oxide layer as a semiconducting layer for a transistor may include but is not limited to 20 flashes at 10 J/cm2, with 500 microsecond pulse length, followed by a thermal annealing step of 350° C. for 30 minutes. Another technique to avoid exceeding a thermal budget on each layer may be to control a ramp rate when performing thermal annealing. This may help minimize thermal shock on a film. Rapid changes in temperature may induce film shrinkage and cracking which may render a film not functional. Desired ramp rates for metal oxide films may range from 5° C./min to 30° C./min. If the ramp rate is much higher than this range, the coefficient of thermal expansion for each of the different materials in the stack and the substrate may start to play a role. In the case where one material expands much faster than another, films may undergo stress leading to cracking, delamination, or peeling and may render the film inactive. If this occurs, the affected layers may have to be removed and redeposited.

A relatively important area of consideration from a group including but not limited to a thermal budget, surface characterization, ink compatibility, energy band alignment, and breakdown prevention, is the area of a surface characterization. Another area could be substrate compatibility. Surface characterization may describe a physical and/or chemical nature of a film and may be separated into two categories a surface morphology and surface energy. A surface characterization may be important in a stack because it may determine how a previous layer may affect a subsequent layer. A surface morphology may describe physical features of a film. One relatively important parameter may be a roughness value of a film. Although a film may appear smooth to a naked eye, it may still have a roughness value typically on an order of hundreds of angstroms to tens of nanometers. This range may be broadened to a single angstrom to hundreds of microns. Typically the smaller a roughness value, the better a film's quality. Typically, roughness values for metal oxide films which may be coated on metal substrates include but may not be limited to; aluminum oxide on aluminum foil of 11.4 nm length, hafnium oxide on aluminum foil of 11.2 nm length, yttrium oxide on aluminum foil of 6.7 nm length. A semiconductor layer in a transistor may have a thickness between 10 nm to 30 nm. This range may be extended to a few atomic layers to hundreds of microns. If a roughness value of a previous layer exceeds or may be semiconductor layer, performance of a semiconducting film may be seriously degraded or become non-functional entirely. This may be because a discontinuous or uneven semiconducting layer may have a lot of trouble transporting electrons. This may degrade many key parameters in a transistor including but not limited to an electron mobility, threshold voltage, and on/off ratio. For a semiconducting layer to work well, a gate oxide layer below it may have a roughness of close to 1 nanometer. One way to achieve this may be to use yttrium oxide as a bottom and top layer in a gate oxide stack with a polymer layer capping everything off. Middle layers in a stack may be other oxides with higher band gaps to reduce leakage current such as aluminum oxide or hafnium oxide. A polymer may be soft and may fill in uneven gaps in metal oxide film, smoothing out a film which may achieve a much lower roughness values. A polymer may need to have a high melting point (greater than 200° C.) and be hydrophilic. Possible polymer candidates include Poly(N-isopropylacrylamide), Polyacrylamide, polyacrylic acid, polymethacrylate, Polyethylenimine, and other acrylic polymers and copolymers. Other possible polymers include poly(2-oxazoline), poly (ethylene glycol), poly(ethylene oxide), poly(vinyl alcohol) and copolymers, poly(vinylpyrrolidone) and copolymers, and polyelectrolytes. A surface energy may describe a chemical nature of a film. A surface energy of a film may determine if a film is hydrophilic or hydrophobic. Metal oxide precursors used here may be hydrophilic, so they may be necessary for a substrate and subsequent layers that may be added to be hydrophilic. This may ensure good ‘wetting’ (a term used to describe how well an ink spreads on a film and how favorable an interaction may be between a film and an ink). A wetting may be important in a stack because it may determine how thick each layer may be (which may determine a stack height) and how wide each layer may be (which may determine a stack width). A metal foil substrate may be hydrophobic by nature and also a good conductor. A hydrophobic substrate may not work well with an RFID tags' inks and a conductor may short any elements that we print on it. This means that a metal foil substrate may need to be passivated (made an insulator) and a passivation may need to make a surface become hydrophilic. There may be two ways that this can be done: silane coupling agent passivation or hydrophilic polymer passivation. In an exemplary embodiment, silane coupling agents may be used for promoting adhesion between inorganic and organic groups. They may be used here as a linker between a metal foil substrate and metal oxide precursor inks that may be subsequently deposited. Silane coupling agents may make a metal foil substrate non-conductive and may achieve good wetting with metal oxide precursor inks. In an exemplary embodiment, processing conditions for a silane coupling agent may include but not be limited to; dropping cast silane coupling agent on to a metal foil substrate and wait for 30 minutes, removing excess silane coupling agent by spin coating at 2000-3000 rpm, baking film between 60-100° C. for one hour. Furthermore, a hydrophilic polymer's requirements may be similar as previously mentioned in a surface morphology section. A polymer may need to have a high melting point (greater than 200° C.) and be hydrophilic. Possible polymer candidates include but may not be limited to; Poly(N-isopropylacrylamide), Polyacrylamide, polyacrylic acid, polymethacrylate, Polyethylenimine, and other acrylic polymers and copolymers. Other possible polymers include poly(2-oxazoline), poly (ethylene glycol), poly(ethylene oxide), poly(vinyl alcohol) and copolymers, poly(vinylpyrrolidone) and copolymers, and polyelectrolytes.

Furthermore still, another area of consideration including but not limited to a thermal budget, surface characterization, ink compatibility, energy band alignment, and breakdown prevention, is an area of a ink compatibility. Another area could be substrate compatibility. When dealing with stacks, it may be important to keep in mind a type of ink that may be applied and a type of film that it may be applied to. Sometimes there may be conflicting properties between ink and film. One example of a conflict may be a weak organic acid treatment. A weak organic acid treatment may be a processing technique to enhance conductivity of solution processed conducting metal oxides. This technique may be used if material for a gate electrode of a transistor was selected to be a conducting metal oxide. Weak organic acid may be inherently incompatible with an oxide as it begins to corrode a surface upon contact. However, in an exemplary embodiment using one of a plurality of processing conditions and guidelines, one may be able to minimize damage to film and actually enhance conductivity of a conducting metal oxide. This enhancement may be important to reduce resistance of a metal oxide to a value that may allow it to serve as a gate electrode. Without this step, an ‘on current’ of a transistor may be severely limited. Material specifications and processing conditions may be as follows. Materials to be used for possible conducting metal oxides include but are not limited to; indium tin oxide, fluorine doped indium tin oxide, indium zinc oxide. Typical sheet resistance of film before treatment may range between 10,000 and 200,000 ohm/square. Possible organic acids used for this process may include but are not limited to methanesulfonic acid, malonic acid, oxalic acid, pyruvic acid, butyric acid, acetic acid, citric acid, ascorbic acid. Other possible organic acids include anthranilic acid, barbituric acid, benzenesulfonic acid, benzoic acid, bromoacetic acid, bromochloroacetic acid, chloroacetic acid, chlorodibromoacetic acid, chlorodifluoroacetic acid, folic acid, fumaric acid, gallic acid, iodoacetic acid, lactic acid, maleic acid, peracetic acid, phthalic acid, salicylic acid, succinic acid, sulfamic acid, tartaric acid, thioacetic acid, thioglycolic acid, toluenesulfonic acid, tribromoacetic acid, trichloroacetic acid, trifluoroacetic acid, trifluoromethanesulfonic acid. Typical concentrations of an acid may range between 0.1M and 10M. Possible solvents may include but are not limited to; deionized water, 2-methoxyethanol, ethanol, methanol. There may be a dropped cast or submerged film in a weak organic acid solution for 3-8 seconds followed by a rinse in deionized water for 15 seconds. Typical sheet resistance of film after treatment may range between 1000 and 10,000 ohm/square. A treatment may effectively lower sheet resistance of a film by about one order of magnitude. However, a treatment may lose its effect after about 24 hours. It may be recommended to deposit subsequent layers immediately after treatment for relatively best results. Furthermore, there may be a solvent selection which may be relatively important to ensure compatibility of film and ink that may be deposited on film. Most of the films in our stack may be either metals or metal oxides. Possible solvents for preparing inks may include but are not limited to the following when they may not have conflicting properties with the films; possible solvents for metal oxide precursor ink may include but are not limited to deionized water, 2-methoxyethanol, ethanol, methanol, acetylacetone. Other possible solvents include oxygen containing organic solvents such as alcohols, ketones or aldehydes as well as oxygen free solvents such as amines or nitriles with short alkyl chains. Additional solvents include toluene or mesitylene.

Furthermore still, another relatively important area of consideration from a group including but not limited to a thermal budget, surface characterization, ink compatibility, energy band alignment, and breakdown prevention, is an area of an energy band alignment. An additional area of consideration may be substrate compatibility. Energy band alignment may be an important concern when designing a transistor stack. A transistor with poorly aligned energy levels may result in a low performing device. Key parameters of a transistor that may be affected include but are not limited to a threshold voltage, on/off ratio and sub-threshold swing. Other parameters include cutoff frequency, subthreshold leakage. When selecting materials for a gate and source/drain electrodes, it may be important to consider a work function value for these materials. Generally, there may be types of materials that one may consider for gate and source/drain electrodes which may include but are not limited to; metals, conducting metal oxides and carbon based derivatives. Typically, metals used for gate and source/drain electrodes may include but are not limited to; gold, silver, aluminum, copper, molybdenum, cobalt. Other metals may include titanium, magnesium, calcium, vanadium, chromium, manganese, iron, nickel, zinc, zirconium, palladium, tantalum, tungsten, platinum, tin, lead. Typically conducting metal oxides may include but are not limited to; indium tin oxide, fluorine doped indium tin oxide, indium zinc oxide. Other conducting metal oxides may include binary or ternary metal oxides. Typically carbon-based derivatives may include but are not limited to; graphene, carbon nanotubes, carbon nanowires, carbon nanoribbons, carbon nanoparticles, and graphite. For a source/drain electrode, it may be desirable to select a material with a relatively low work function (typically less than 4.2 eV). This may ensure that a metal semiconductor interface may not create a Shockley barrier. A Shockley barrier may make it more difficult for electrons to travel from a semiconductor to the source/drain electrode. Conducting metal oxides may be a good choice in terms of energy band alignment with a semiconductor layer of an RFID tag. However, in an exemplary embodiment, a drawback of using conducting metal oxides may be that lower conductivity may be compared to metals'. This limitation may be overcome by using a sandwich structure, which may place a thin layer of metal (typically on an order of 10 nanometers in an exemplary embodiment) between two conducting metal oxides (thickness typically ranging from 20 to 100 nanometers in an exemplary embodiment). This structure may enable a well aligned energy level with a semiconductor layer while maintaining a conductivity close to that of metals.

Furthermore still, another relatively important area of consideration from a group including but not limited to a thermal budget, surface characterization, ink compatibility, energy band alignment, and breakdown prevention, is an area of a breakdown prevention. Another area may include substrate compatibility. Solution processed devices may be inherently prone to breakdown under high electric field. This may limit a voltage range that these devices may operate in. Metal oxides deposited using a vacuum-based deposition methods may typically handle electric fields greater than 6 MV/cm. This means that the operating voltages may exceed over 50 volts for source/drain voltage and source/gate voltage depending on a thickness of a gate insulator. Although typical operating conditions may not need to reach such high voltages, an ability for vacuum based films to withstand high electric fields may be a benefit that solution processed devices may need to overcome. In an exemplary embodiment, there may be a plurality of ways for solution processed devices to overcome this challenge. Each of the methods may be described in detail below. A relatively simple way to limit breakdown from happening may be to simply apply multiple coatings of a same layer. This may increase an overall film thickness and allow it to withstand higher electric fields. In an exemplary embodiment and in terms of a gate insulator layer, a minimum thickness that may be used may be 100 nanometers, which may translate to between 4 to 8 coats depending on a type of ink which may be used. This range can be extended to 1 to 20 coats. One possible draw-backs for using a thicker layer for a gate insulator may be a decreased capacitance a gate insulator can provide. A lower capacitance may result in a lower current for a transistor. One of a plurality of simple processing techniques which may be used to enhance film quality and increase its ability to withstand higher electric fields may include but not be limited to UV treatment. High energy photons from UV treatment may provide additional energy to film that may allow a metal oxide precursor to become a dense metal oxide film. UV treatment may be used concurrently during an annealing process or as a separate step before annealing. In an exemplary embodiment there may be two relatively preferred UV treatment procedures for an IGZO film would be as follows; 1. A UV treatment may be applied for 30 minutes followed by thermal annealing at 350° C. for 1 hour; 2. UV and thermal annealing concurrently at 350° C. for 1 hour. In general, any temperature range above 150° C. annealed for more than 30 minutes should result in a functional film, although it may not be a very good film. Less than 150° C. will most likely result in an inactive film. One of plural major reasons why solution processed films may have poorer electrical breakdown characteristics compared to vacuum based deposited films include but are not limited to it being due to a low film density. Typical solution processed metal oxide films have about 50 to 80% of a density of bulk material.

One reason for the low film density includes but is not limited to because of porosities that may result in a film during an anneal step. One way to reduce the porosity in a film is to start with precursors that have less impurities or counter ions. This will reduce the amount of material that needs escape from the film during the metal oxide network formation and consequently reduce the amount of porous area in the film. During an anneal step, excess solvent and other impurities in a precursor may evaporate and result in a large volume loss in film. This may create a porous film which may be prone to electrical breakdown. One final method may be to select materials that may have a higher resistance to electrical breakdown and incorporate them into a stack. Materials with large band gaps may be alternately layered with materials with high dielectric constants. Materials with high band gaps include silicon dioxide, aluminum dioxide, yttrium aluminum oxide, magnesium oxide, calcium oxide, zirconium silicon oxide, hafnium silicon oxide, silicon nitride. This may create a gate insulator stack that may have a low leakage current and high capacitance along with increased resistance to electrical breakdown. Typically, an inkjet printing may allow a tag to be built using an additive manufacturing technique without a need for masks. This technology may enable large scale manufacturing with minimum waste of precursors. A requirement for using inkjet printing may be that an ink needs to be particle free. If an ink has any particulates, even if particles may be relatively very small, they may end up clogging nozzles of an inkjet head. An inkjet printer may deposit droplets on an order of pico-liters so even small particulates in an ink may become troublesome. A surface energy of a substrate or a film being printed on may be critical for producing features with correct size and shape. As previously mentioned, metal oxide precursor ink may be hydrophilic so film being deposited on should also be hydrophilic. Aforementioned techniques (including but not limited to silane coupling, hydrophilic polymer, UV treatment, photonic curing and/or plasma treatment.) may all be used to make the surface more hydrophilic. Suitable techniques may depend on a stack being built and specific material properties of that stack. Besides tuning properties of film, an ink may also be adjusted to be more favorable for inkjet deposition. Parameters that may be adjusted in ink may include but are not limited to viscosity, pH, and tack time. Other parameters include surface tension, concentration, and doping. These parameters may be adjusted by adding additives such as ethylene glycol, acetic acid, acetylacetone, ammonium hydroxide and many others into the precursor such as but not limited to weak acids or bases and polymers.

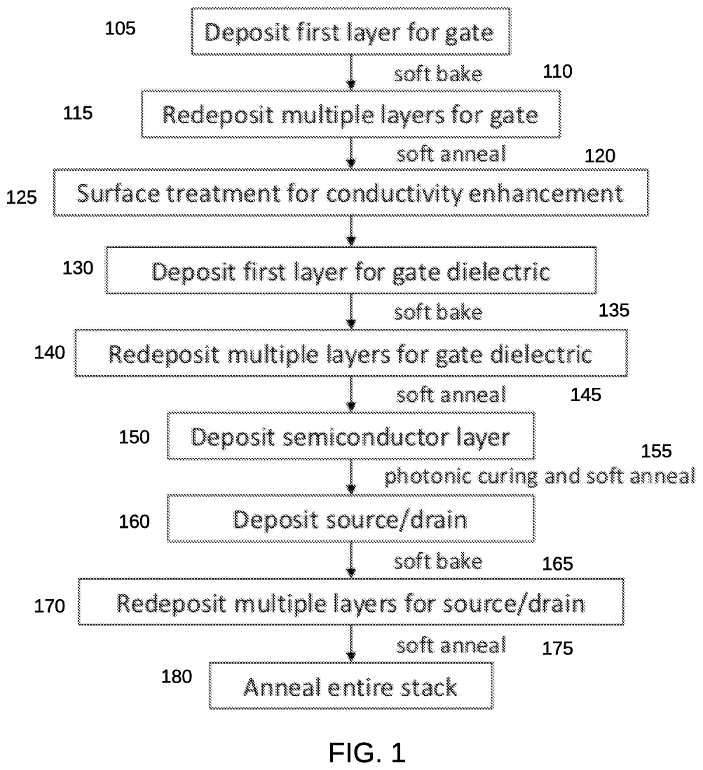

FIG. 1 illustrates a representative process flow diagram for building the transistor stack, in accordance with an embodiment of the invention. In a Step 105 a first layer is deposited. This layer is the first layer of the gate electrode. Materials for this layer include metals, conducting metal oxides, and carbon based derivatives. In a Step 110 a RFID tag may be soft baked, where a soft bake technique may be useful when layering multiple coatings of a same ink. Furthermore still, in alternative embodiment the RFID tag may be baked relatively higher or lower temperature/timing conditions compared to soft baking. A soft bake may be performed at a lower temperature than a required annealing temperature and for a shorter amount of time. In general, any temperature range above 150° C. annealed for more than 30 minutes should result in a functional film, although it may not be a very good film. Less than 150° C. will most likely result in an inactive film. A goal for soft baking may be to remove a solvent from an ink and induce metal oxide network formation so a next coating may not dissolve a previous coating. In an exemplary embodiment, when building a gate insulator, it may be beneficial to layer multiple coatings of a same ink. For this exemplary embodiment, it may use a chemical compound including but not limited to aluminum oxide. Other alternatives for gate insulator material include lanthanum oxide, hafnium oxide, silicon oxide, zirconium oxide, silicon oxynitride, tantalum oxide, silicon nitride, yttrium oxide, titanium oxide, germanium oxide, binary and ternary based oxides, and polymer based materials. In an exemplary embodiment, a precursor for aluminum oxide may be annealed at 250° C. for 1 hour. In an exemplary embodiment, a soft bake technique may anneal each layer for 10 minutes at 200° C. Furthermore still, in alternative embodiment the RFID tag may have its temperatures and/or timing adjusted to customize fabrication. In a Step 115 multiple layers for gate may be redeposited. In a Step 120 there may be a soft anneal performed on the RFID tag. In a Step 120 a soft anneal process may be a technique which may be useful when layering different ink types. A soft anneal may be performed at a required temperature to drive a desired reaction to occur, but not to completion. In an exemplary embodiment, for a previous aluminum oxide example, a soft anneal may be performed at 250° C. for 30 minutes. In general, any temperature range above 150° C. annealed for more than 30 minutes should result in a functional film, although it may not be a very good film. Less than 150° C. will most likely result in an inactive film. In a Step 125 there may be surface treatment performed for conductivity enhancement. This conductivity enhancement may be important to reduce the resistance value of a metal oxide to a resistance value that may allow it to serve as a gate electrode. In a Step 130 there may be a first layer deposited for a gate dielectric. A dielectric material may be selected from aluminum oxide, hafnium oxide, zirconium oxide, silicon dioxide, or a combination thereof. Other alternatives for gate insulator material include lanthanum oxide, hafnium oxide, silicon oxide, zirconium oxide, silicon oxynitride, tantalum oxide, silicon nitride, yttrium oxide, titanium oxide, germanium oxide, binary and ternary based oxides, and polymer based materials. In a Step 135 there may be a soft bake performed on the RFID tag, this soft bake process may be similar to the soft bake in Step 110. In a Step 140 there may be multiple layers redeposited for a gate dielectric. In a Step 145 there may be a soft anneal process performed on the RFID tag, where a soft anneal process may be similar to the previous soft anneal performed in this process. In a Step 150 there may be a semiconductor layer deposited in the transistor. In a Step 155 there may be photonic curing and a soft anneal processes performed. A soft annealing process may be similar to a previous soft annealing performed. A photonic curing technique may rely on a high-powered xenon lamp to deliver large amounts of energy in a relatively very short amount of time. A goal for Step 155 may be to heat up only a top layer in a stack without affecting everything below it. Furthermore still, in alternative embodiment the RFID tag may be more selectively heated or less region specifically heated. This technique may be useful for annealing a semiconducting layer in a transistor and also interconnects. Commercially available photonic curing equipment may allow for tuning of processing conditions to meet needs of a material being annealed. In an exemplary embodiment, for metal oxide precursors used in a RFID tag, a following processing condition may generally result in functioning devices: a number of flashes: may range between 1-35, radiant energy delivered: may range between 5-45 J/cm2, pulse length: may range between 500-50,000 microseconds. output spectrum: between 200-1500 nanometers, a photonic curing technique may be followed by a thermal annealing step (depending on a thermal budget of a stack) to improve a performance of a target layer. Ranges for these values may be broadened as follows. Radiant energy delivered: 1-45 J/cm2. Pulse length: 25-100,000 microseconds. In an exemplary embodiment, processing conditions for an Indium Gallium Zinc Oxide layer as a semiconducting layer for the transistor may include: 20 flashes at 10 J/cm2 with 500 microsecond pulse length followed by a thermal annealing step of 350° C. for 30 minutes, ramp rate: a ramp rate when performing a thermal annealing is an important parameter to help minimize thermal shock on the film. In general rapid changes in temperature may induce film shrinkage and cracking that may render a film non-functional. This ramp rate range can be broadened to 1 to 50 ° C./min. In an exemplary embodiment, desired ramp rates for metal oxide films may range from 5° C./min to 30° C./min. If the ramp rate is much higher than this range, the coefficient of thermal expansion for each of the different materials in the stack and the substrate may start to play a role. In the case where one material expands much faster than another, films may undergo stress leading to cracking, delamination, or peeling and may render the film inactive. If this occurs, the affected layers may have to be removed and redeposited. In a Step 160 a source and drain may be deposited. Solution processed deposition methods may be selected from inkjet printing, spin coating, dip coating, blade coating, bar coating, gravure printing, spray coating, or screen printing In a Step 165 a soft bake process may be performed, similarly to how a soft bake process was performed in earlier steps. In a Step 170 there may be multiple layers redeposited for a source and drain. In a Step 175 there may be a soft anneal performed, similarly to how a soft anneal process was performed in earlier steps. Steps 180 there may be an entire stack annealed similar to previous annealing process. Furthermore still, in alternative embodiment the RFID tag may have its fabrication steps rearranged or edited to better customize a RFID tag.

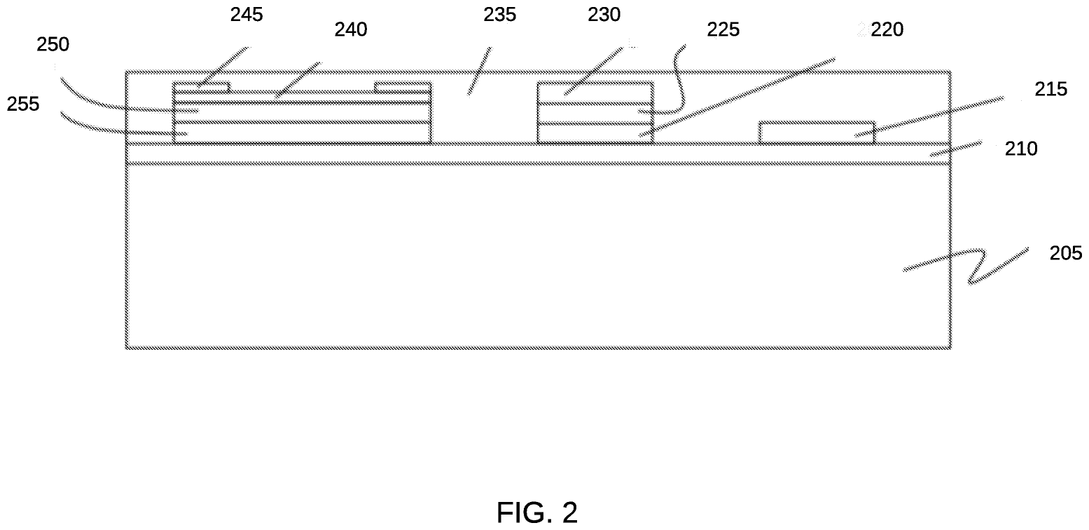

FIG. 2 illustrates a cross-sectional view of structure for a fully printed inorganic passive RFID tag, in accordance with an embodiment of the invention. Elements in FIG. 2 may include but are not limited to a transistor, capacitor, resistor 215, a metal foil substrate 205 and passive layer/ passivation 210 and encapsulation 235 for the RFID tag. Other elements may include inductors, interconnects, vias, diodes, switches. Furthermore still, in alternative embodiment the RFID tag may be composed of relatively more complex or less complex circuit layouts and elements. In reference to FIG. 1 and FIG. 2, layers in FIG. 2 may be deposited onto a substrate according to the process in FIG. 1. A substrate for the RFID tag may include materials including but not limited to metal foil. Other types of substrates may include, but not limited to, glass based substrates, polymer based substrates, silicon based substrates, ceramic based substrates or composite materials. In an exemplary embodiment there may be a substrate made of glass used, but this may limit flexibility and therefore may limit applications where this may be mounted and durability. A metal foil substrate 205 may be “hydrophobic” by nature and may also be a good conductor. Typical metal conductivities may range from 10\hat{ }6-10\hat{ }7 S/m. A hydrophobic substrate may not work well with some inks and a conductor may short any elements that we print on it. This means that a metal foil substrate 205 may need to be passivated (made an insulator) and the passivation may need to make a surface become hydrophilic. Therefore, on top of a metal foil substrate 205, there may be a passive layer/passivation 210. There may be two ways that passivation may be done: silane coupling agent passivation or hydrophilic polymer passivation. If silane coupling agent passivation is used: silane coupling agents may be used for promoting adhesion between inorganic and organic groups. Silane coupling agents may be used here as a linker between a metal foil substrate and a metal oxide precursor inks that may be subsequently deposited. Silane coupling agents may make a metal foil substrate nonconductive and achieve good wetting with metal oxide precursor inks. Processing for a silane coupling agent may be as follows: dropping casting a silane coupling agent on to a metal foil substrate 205 and waiting for 30 minutes, excess silane coupling agent may be removed by spin coating at 2000-3000 rpm, then a film may be baked between 60-100° C. for one hour. If hydrophilic polymer passivation is used: a polymer may need to have a high melting point (greater than 200° C.) and be hydrophilic. Possible polymer candidates may include but are not limited to Poly(N-isopropylacrylamide), Polyacrylamide, polyacrylic acid, polymethacrylate, Polyethylenimine, and other acrylic polymers and copolymers. Other possible polymers include poly(2-oxazoline), poly (ethylene glycol), poly(ethylene oxide), poly(vinyl alcohol) and copolymers, poly(vinylpyrrolidone) and copolymers, and polyelectrolytes. Above the passivation 210 there may be several elements including but not limited to a resistor or metal line 215, a conductor or metal line 220, and a gate 255. Other elements may include inductors, interconnects, vias, diodes, switches. Above a resistor or metal line 215 there may only be encapsulation 235. Gate dielectric, semiconductor layer. An encapsulation 235 may include using a solution-based processes, and an active layer of each transistor may be made with a solution processed inorganic ink. When dealing with stacks, one may need to keep in mind which type of ink may be applied, and which type of film it may be applied to. Sometimes there may be conflicting properties between ink and film. One example of this may be a weak organic acid treatment, where this may be a processing technique to enhance a conductivity of solution processed conducting metal oxides. Over a conductor or metal line 220 there may be a dielectric 225, which may have a conductor or metal line 230 over it. The dielectric 225 may have a conductor or metal line 230, which may be made from materials including but not limited to gold, silver, aluminum, copper, carbon-based derivatives, single component conducting metal oxide, binary conducting metal oxide, ternary conducting metal oxide, or multi-component conducting metal oxide. Other materials may include titanium, magnesium, calcium, vanadium, chromium, manganese, iron, nickel, zinc, zirconium, palladium, tantalum, tungsten, platinum, tin, lead, cobalt, molybdenum. Furthermore still, in alternative embodiment the RFID tag may be made from future new elements which may be related to these materials or a practical alternative material. Layered above a gate 255 there may be a gate dielectric 250, which may have a layer above it of semiconductor 240 material, which may have two separate layers above it of source and drain contacts 245. Above a conductor or metal line 220 there may be a dielectric 225, and on top of a dielectric 225 there may be a conductor or metal line 230. A dielectric 225 may be made from materials including but not limited to aluminum oxide, hafnium oxide, zirconium oxide, silicon dioxide or a combination thereof. Other alternatives for dielectric material include lanthanum oxide, hafnium oxide, silicon oxide, zirconium oxide, silicon oxynitride, tantalum oxide, silicon nitride, yttrium oxide, titanium oxide, germanium oxide, binary and ternary based oxides, and polymer based materials.

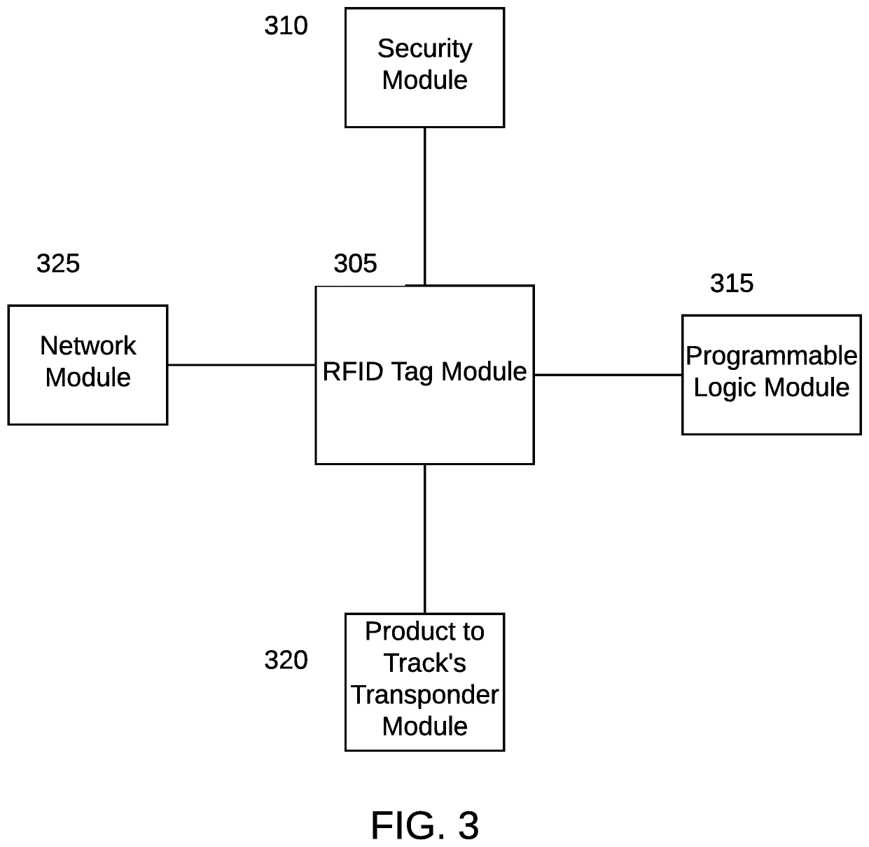

FIG. 3 illustrates an exemplary software system modules architecture for an RFID tag. When an RFID tag may be in use there may be an RFID tag module 305 which may carry out processes including but not limited to, controlling an appropriate ping and/or response, and/ or controlling and updating additional modules. A response may be to help track a product by processing data related to information including but not limited to location, current time information, destination information, or any other information which may be received from another module. Other useful data may include manufacturing origin, material composition, year of production, and model number. An RFID tag module 305 may furthermore interface with a Programmable Logic Module 315 which may control logic in general and compute data relation calculations, which may include but are not limited to database information identifying products, tracking its location history, and/or what to do when there is a problematic issue. An RFID tag module 305 may furthermore interface with a Security Module 310 which may process data related to but not limited to a security protocol for a transponder, alerting if there may be a breach or attempted breach, and/or storing authentication data. The Security Module 310 will not only store the data but may also encrypt and decrypt the data. An RFID tag module 305 may furthermore interface with a network module 325 to access an outside network which may contain information including but not limited to product information, manufacturing information, updates to manufacturing or product information, and/or updates to any module involved. Furthermore still, in alternative embodiment the RFID tag may be connected to a close by “smart” device where it may access more computing capability. An RFID tag module 305 may furthermore interface with a product to track's module 320 which may process data related to but not limited to a product's ID, a product's intended location, and/or a product's future locations. Another module that the RFID tag module may interface with is a Storage Module that will contain information including but not limited to product information, manufacturing information, process information. The Storage Module allows storing the information in the RFID tag itself rather than redirecting the reader to an outside storage, making the stored data harder to breach.

Those skilled in the art will readily recognize, in light of and in accordance with the teachings of the present invention, that any of the foregoing steps and/or system modules may be suitably replaced, reordered, removed and additional steps and/or system modules may be inserted depending upon the needs of the particular application, and that the systems of the foregoing embodiments may be implemented using any of a wide variety of suitable processes and system modules, and is not limited to any particular computer hardware, software, middleware, firmware, microcode and the like. For any method steps described in the present application that can be carried out on a computing machine, a typical computer system can, when appropriately configured or designed, serve as a computer system in which those aspects of the invention may be embodied.

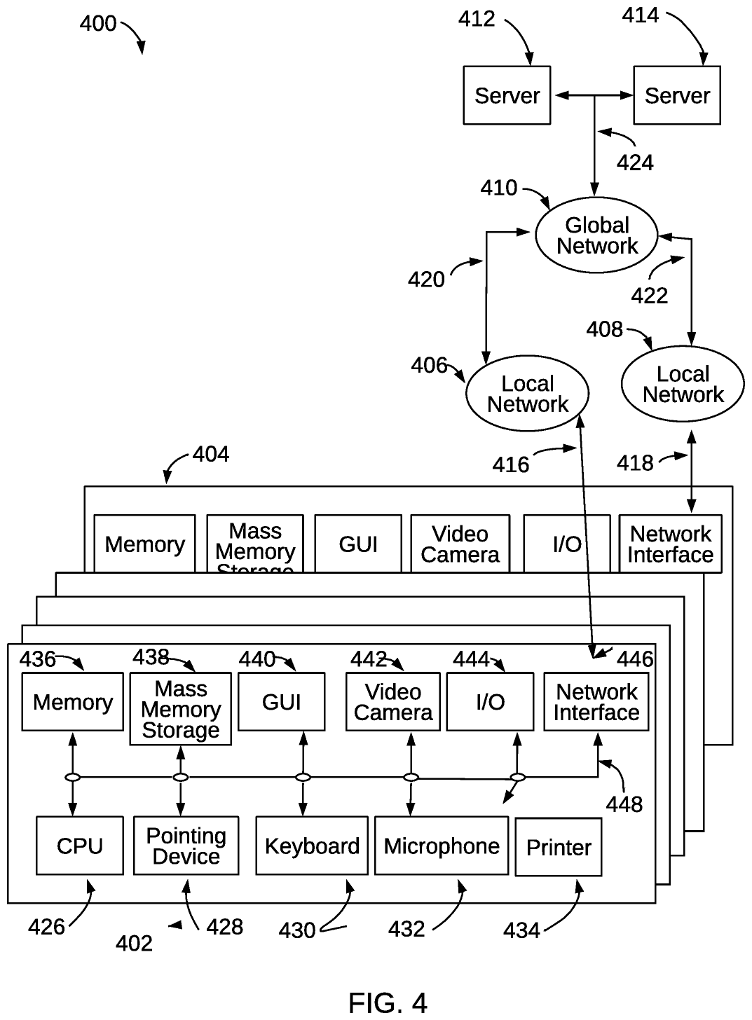

FIG. 4 is a block diagram depicting an exemplary client/server system which may be used by an exemplary web-enabled/networked embodiment of the present invention.

A communication system 400 includes a multiplicity of clients with a sampling of clients denoted as a client 402 and a client 404, a multiplicity of local networks with a sampling of networks denoted as a local network 406 and a local network 408, a global network 410 and a multiplicity of servers with a sampling of servers denoted as a server 412 and a server 414.

Client 402 may communicate bi-directionally with local network 406 via a communication channel 416. Client 404 may communicate bi-directionally with local network 408 via a communication channel 418. Local network 406 may communicate bi-directionally with global network 410 via a communication channel 420. Local network 408 may communicate bi-directionally with global network 410 via a communication channel 422. Global network 410 may communicate bi-directionally with server 412 and server 414 via a communication channel 424. Server 412 and server 414 may communicate bi-directionally with each other via communication channel 424. Furthermore, clients 402, 404, local networks 406, 408, global network 410 and servers 412, 414 may each communicate bi-directionally with each other.

In one embodiment, global network 410 may operate as the Internet. It will be understood by those skilled in the art that communication system 400 may take many different forms. Non-limiting examples of forms for communication system 400 include local area networks (LANs), wide area networks (WANs), wired telephone networks, wireless networks, or any other network supporting data communication between respective entities.

Clients 402 and 404 may take many different forms. Non-limiting examples of clients 402 and 404 include personal computers, personal digital assistants (PDAs), cellular phones and smartphones.

Client 402 includes a CPU 426, a pointing device 428, a keyboard 430, a microphone 432, a printer 434, a memory 436, a mass memory storage 438, a GUI 440, a video camera 442, an input/output interface 444 and a network interface 446.

CPU 426, pointing device 428, keyboard 430, microphone 432, printer 434, memory 436, mass memory storage 438, GUI 440, video camera 442, input/output interface 444 and network interface 446 may communicate in a unidirectional manner or a bi-directional manner with each other via a communication channel 448.

Communication channel 448 may be configured as a single communication channel or a multiplicity of communication channels.

CPU 426 may be comprised of a single processor or multiple processors. CPU 426 may be of various types including micro-controllers (e.g., with embedded RAM/ROM) and microprocessors such as programmable devices (e.g., RISC or SISC based, or CPLDs and FPGAs) and devices not capable of being programmed such as gate array ASICs (Application Specific Integrated Circuits) or general purpose microprocessors.

As is well known in the art, memory 436 is used typically to transfer data and instructions to CPU 426 in a bi-directional manner. Memory 436, as discussed previously, may include any suitable computer-readable media, intended for data storage, such as those described above excluding any wired or wireless transmissions unless specifically noted. Mass memory storage 438 may also be coupled bi-directionally to CPU 426 and provides additional data storage capacity and may include any of the computer-readable media described above. Mass memory storage 438 may be used to store programs, data and the like and is typically a secondary storage medium such as a hard disk. It will be appreciated that the information retained within mass memory storage 438, may, in appropriate cases, be incorporated in standard fashion as part of memory 436 as virtual memory.

CPU 426 may be coupled to GUI 440. GUI 440 enables a user to view the operation of computer operating system and software. CPU 426 may be coupled to pointing device 428. Non-limiting examples of pointing device 428 include computer mouse, trackball and touchpad. Pointing device 428 enables a user with the capability to maneuver a computer cursor about the viewing area of GUI 440 and select areas or features in the viewing area of GUI 440. CPU 426 may be coupled to keyboard 430. Keyboard 430 enables a user with the capability to input alphanumeric textual information to CPU 426. CPU 426 may be coupled to microphone 432. Microphone 432 enables audio produced by a user to be recorded, processed and communicated by CPU 426. CPU 426 may be connected to printer 434. Printer 434 enables a user with the capability to print information to a sheet of paper. CPU 426 may be connected to video camera 442. Video camera 442 enables video produced or captured by user to be recorded, processed and communicated by CPU 426.

CPU 426 may also be coupled to input/output interface 444 that connects to one or more input/output devices such as such as CD-ROM, video monitors, track balls, mice, keyboards, microphones, touch-sensitive displays, transducer card readers, magnetic or paper tape readers, tablets, styluses, voice or handwriting recognizers, or other well-known input devices such as, of course, other computers.

Finally, CPU 426 optionally may be coupled to network interface 446 which enables communication with an external device such as a database or a computer or telecommunications or internet network using an external connection shown generally as communication channel 416, which may be implemented as a hardwired or wireless communications link using suitable conventional technologies. With such a connection, CPU 426 might receive information from the network, or might output information to a network in the course of performing the method steps described in the teachings of the present invention.

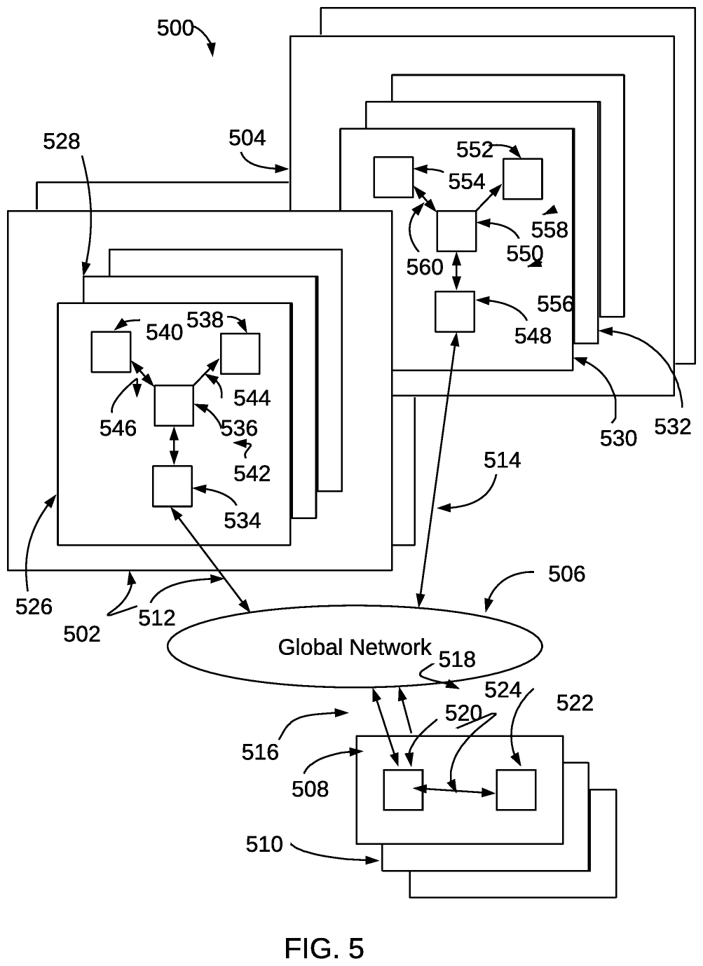

FIG. 5 illustrates a block diagram depicting a conventional client/server communication system. A communication system 500 includes a multiplicity of networked regions with a sampling of regions denoted as a network region 502 and a network region 504, a global network 506 and a multiplicity of servers with a sampling of servers denoted as a server device 508 and a server device 510.

Network region 502 and network region 504 may operate to represent a network contained within a geographical area or region. Non-limiting examples of representations for the geographical areas for the networked regions may include postal zip codes, telephone area codes, states, counties, cities and countries. Elements within network region 502 and 504 may operate to communicate with external elements within other networked regions or within elements contained within the same network region.

In some implementations, global network 506 may operate as the Internet. It will be understood by those skilled in the art that communication system 500 may take many different forms. Non-limiting examples of forms for communication system 500 include local area networks (LANs), wide area networks (WANs), wired telephone networks, cellular telephone networks or any other network supporting data communication between respective entities via hardwired or wireless communication networks. Global network 506 may operate to transfer information between the various networked elements.

Server device 508 and server device 510 may operate to execute software instructions, store information, support database operations and communicate with other networked elements. Non-limiting examples of software and scripting languages which may be executed on server device 508 and server device 510 include C, C++, C# and Java.

Network region 502 may operate to communicate bi-directionally with global network 506 via a communication channel 512. Network region 504 may operate to communicate bi-directionally with global network 506 via a communication channel 514. Server device 508 may operate to communicate bi-directionally with global network 506 via a communication channel 516. Server device 510 may operate to communicate bi-directionally with global network 506 via a communication channel 518. Network region 502 and 504, global network 506 and server devices 508 and 510 may operate to communicate with each other and with every other networked device located within communication system 500.

Server device 508 includes a networking device 520 and a server 522. Networking device 520 may operate to communicate bi-directionally with global network 506 via communication channel 516 and with server 522 via a communication channel 524. Server 522 may operate to execute software instructions and store information.

Network region 502 includes a multiplicity of clients with a sampling denoted as a client 526 and a client 528. Client 526 includes a networking device 534, a processor 536, a GUI 538 and an interface device 540. Non-limiting examples of devices for GUI 538 include monitors, televisions, cellular telephones, smartphones and PDAs (Personal Digital Assistants). Non-limiting examples of interface device 540 include pointing device, mouse, trackball, scanner and printer. Networking device 534 may communicate bi-directionally with global network 506 via communication channel 512 and with processor 536 via a communication channel 542. GUI 538 may receive information from processor 536 via a communication channel 544 for presentation to a user for viewing. Interface device 540 may operate to send control information to processor 536 and to receive information from processor 536 via a communication channel 546. Network region 504 includes a multiplicity of clients with a sampling denoted as a client 530 and a client 532. Client 530 includes a networking device 548, a processor 550, a GUI 552 and an interface device 554. Non-limiting examples of devices for GUI 538 include monitors, televisions, cellular telephones, smartphones and PDAs (Personal Digital Assistants). Non-limiting examples of interface device 540 include pointing devices, mousse, trackballs, scanners and printers. Networking device 548 may communicate bi-directionally with global network 506 via communication channel 514 and with processor 550 via a communication channel 556. GUI 552 may receive information from processor 550 via a communication channel 558 for presentation to a user for viewing. Interface device 554 may operate to send control information to processor 550 and to receive information from processor 550 via a communication channel 560.

For example, consider the case where a user interfacing with client 526 may want to execute a networked application. A user may enter the IP (Internet Protocol) address for the networked application using interface device 540. The IP address information may be communicated to processor 536 via communication channel 546. Processor 536 may then communicate the IP address information to networking device 534 via communication channel 542. Networking device 534 may then communicate the IP address information to global network 506 via communication channel 512. Global network 506 may then communicate the IP address information to networking device 520 of server device 508 via communication channel 516. Networking device 520 may then communicate the IP address information to server 522 via communication channel 524. Server 522 may receive the IP address information and after processing the IP address information may communicate return information to networking device 520 via communication channel 524. Networking device 520 may communicate the return information to global network 506 via communication channel 516. Global network 506 may communicate the return information to networking device 534 via communication channel 512. Networking device 534 may communicate the return information to processor 536 via communication channel 542. Processor 556 may communicate the return information to GUI 558 via communication channel 544. User may then view the return information on GUI 538.

It is noted that according to USA law, all claims must be set forth as a coherent, cooperating set of limitations that work in functional combination to achieve a useful result as a whole. Accordingly, for any claim having functional limitations interpreted under 35 USC § 112 (6) where the embodiment in question is implemented as a client-server system with a remote server located outside of the USA, each such recited function is intended to mean the function of combining, in a logical manner, the information of that claim limitation with at least one other limitation of the claim. For example, in client-server systems where certain information claimed under 35 USC § 112 (6) is/(are) dependent on one or more remote servers located outside the USA, it is intended that each such recited function under 35 USC § 112 (6) is to be interpreted as the function of the local system receiving the remotely generated information required by a locally implemented claim limitation, wherein the structures and or steps which enable, and breath life into the expression of such functions claimed under 35 USC § 112 (6) are the corresponding steps and/or means located within the jurisdiction of the USA that receive and deliver that information to the client (e.g., without limitation, client-side processing and transmission networks in the USA). When this application is prosecuted or patented under a jurisdiction other than the USA, then “USA” in the foregoing should be replaced with the pertinent country or countries or legal organization(s) having enforceable patent infringement jurisdiction over the present application, and “35 USC § 112 (6)” should be replaced with the closest corresponding statute in the patent laws of such pertinent country or countries or legal organization(s).

All the features disclosed in this specification, including any accompanying abstract and drawings, may be replaced by alternative features serving the same, equivalent or similar purpose, unless expressly stated otherwise. Thus, unless expressly stated otherwise, each feature disclosed is one example only of a generic series of equivalent or similar features.

It is noted that according to USA law 35 USC § 112 (1), all claims must be supported by sufficient disclosure in the present patent specification, and any material known to those skilled in the art need not be explicitly disclosed. However, 35 USC § 112 (6) requires that structures corresponding to functional limitations interpreted under 35 USC § 112 (6) must be explicitly disclosed in the patent specification. Moreover, the USPTO's Examination policy of initially treating and searching prior art under the broadest interpretation of a “mean for” or “steps for” claim limitation implies that the broadest initial search on 35 USC § 112(6) (post AIA 112(f)) functional limitation would have to be conducted to support a legally valid Examination on that USPTO policy for broadest interpretation of “mean for” claims. Accordingly, the USPTO will have discovered a multiplicity of prior art documents including disclosure of specific structures and elements which are suitable to act as corresponding structures to satisfy all functional limitations in the below claims that are interpreted under 35 USC § 112(6) (post AIA 112(f)) when such corresponding structures are not explicitly disclosed in the foregoing patent specification. Therefore, for any invention element(s)/structure(s) corresponding to functional claim limitation(s), in the below claims interpreted under 35 USC § 112(6) (post AIA 112(f)), which is/are not explicitly disclosed in the foregoing patent specification, yet do exist in the patent and/or non-patent documents found during the course of USPTO searching, Applicant(s) incorporate all such functionally corresponding structures and related enabling material herein by reference for the purpose of providing explicit structures that implement the functional means claimed. Applicant(s) request(s) that fact finders during any claims construction proceedings and/or examination of patent allowability properly identify and incorporate only the portions of each of these documents discovered during the broadest interpretation search of 35 USC § 112(6) (post AIA 112(f)) limitation, which exist in at least one of the patent and/or non-patent documents found during the course of normal USPTO searching and or supplied to the USPTO during prosecution. Applicant(s) also incorporate by reference the bibliographic citation information to identify all such documents comprising functionally corresponding structures and related enabling material as listed in any PTO Form-892 or likewise any information disclosure statements (IDS) entered into the present patent application by the USPTO or Applicant(s) or any 3^{rd} parties. Applicant(s) also reserve its right to later amend the present application to explicitly include citations to such documents and/or explicitly include the functionally corresponding structures which were incorporate by reference above.

Thus, for any invention element(s)/structure(s) corresponding to functional claim limitation(s), in the below claims, that are interpreted under 35 USC § 112(6) (post AIA 112(f)), which is/are not explicitly disclosed in the foregoing patent specification, Applicant(s) have explicitly prescribed which documents and material to include the otherwise missing disclosure, and have prescribed exactly which portions of such patent and/or non-patent documents should be incorporated by such reference for the purpose of satisfying the disclosure requirements of 35 USC § 112 (6). Applicant(s) note that all the identified documents above which are incorporated by reference to satisfy 35 USC § 112 (6) necessarily have a filing and/or publication date prior to that of the instant application, and thus are valid prior documents to incorporated by reference in the instant application.

Having fully described at least one embodiment of the present invention, other equivalent or alternative methods of implementing an RFID tag according to the present invention will be apparent to those skilled in the art. Various aspects of the invention have been described above by way of illustration, and the specific embodiments disclosed are not intended to limit the invention to the particular forms disclosed. The particular implementation of an RFID tag may vary depending upon the particular context or application. By way of example, and not limitation, the RFID tag described in the foregoing were principally directed to manufacturing piece product tracking implementations; however, similar techniques may instead be applied to tracking products in general, inexpensive database processing for product inventories, tracking pets/children/elderly/medicine/anything physical, to which implementations of the present invention are contemplated as within the scope of the present invention. The invention is thus to cover all modifications, equivalents, and alternatives falling within the spirit and scope of the following claims. It is to be further understood that not all of the disclosed embodiments in the foregoing specification will necessarily satisfy or achieve each of the objects, advantages, or improvements described in the foregoing specification.

Claim elements and steps herein may have been numbered and/or lettered solely as an aid in readability and understanding. Any such numbering and lettering in itself is not intended to and should not be taken to indicate the ordering of elements and/or steps in the claims.

The corresponding structures, materials, acts, and equivalents of all means or step plus function elements in the claims below are intended to include any structure, material, or act for performing the function in combination with other claimed elements as specifically claimed.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

The Abstract is provided to comply with 37 C.F.R. Section 1.72(b) requiring an abstract that will allow the reader to ascertain the nature and gist of the technical disclosure. That is, the Abstract is provided merely to introduce certain concepts and not to identify any key or essential features of the claimed subject matter. It is submitted with the understanding that it will not be used to limit or interpret the scope or meaning of the claims.

The following claims are hereby incorporated into the detailed description, with each claim standing on its own as a separate embodiment.

What is claimed is:

1. A method comprising:
depositing a first layer of a tag on a substrate, in which said first layer comprises at least one of, a metal oxide and carbon based derivative;
baking said first layer at a first predetermined temperature;
depositing a second layer, in which said second layer comprises at least one of said metal oxide and carbon based derivative layer;
annealing said second layer;
treating a surface of said second layer, wherein said surface treatment is configured to enhance conductivity;
depositing a third layer, in which said third layer comprises at least one of, an aluminum oxide, a hafnium oxide, a zirconium oxide, and a silicon dioxide layer; and
baking said third layer at a second predetermined temperature.

2. The method of claim 1, wherein said first layer is a gate electrode of said tag, in which said tag comprises at least one of, an RFID tag, RFID label, an RF tag, an NFC tag, a passive tag, and an active tag.

3. The method of claim 2, wherein said third layer is a gate dielectric of said tag.

4. The method of claim 3, further comprising depositing a fourth layer, in which said fourth layer comprises at least one of said aluminum oxide, hafnium oxide, zirconium oxide, and silicon dioxide layer.

5. The method of claim 4, further comprising annealing said fourth layer.

6. The method of claim 5, further comprising depositing a fifth layer, in which said fifth layer comprises at least an Indium Gallium Zinc Oxide layer.

7. The method of claim 6, further comprising photonic curing said fifth layer.

8. The method of claim 7, in which said fifth layer is a semiconductor layer of said tag.

9. The method of claim 8, further comprising depositing a sixth and seventh layer, in which said sixth layer comprises at least one of, a metal oxide and carbon based derivative.

10. The method of claim 9, further comprising baking said deposited sixth and seventh layer at a third predetermined temperature.

11. The method of claim 13, in which said sixth layer is a source and said seventh layer is a drain.

12. The method of claim 12, further comprising depositing an eight layer, in which said eighth layer comprises at least one of, a metal oxide and carbon based derivative.

13. The method of claim 12, further comprising annealing said deposited layers.

14. The method of claim 1, in which said substrate comprises a metal foil.

15. The method of claim 14, wherein said metal foil is a thin metal foil selected from copper, stainless steel, nickel or nickel alloy, cobalt or cobalt alloy, titanium or titanium alloy, aluminum or aluminum alloy.

16. The method of claim 13, in which said depositing comprises at least one of, inkjet printing, spin coating, dip coating, blade coating, bar coating, gravure printing, spray coating, and screen printing, wherein said tag is encapsulated using solution based processes and the active layer of each transistor is made with solution processed inorganic ink.

17. The method of claim 15, in which a digital logic portion of the tag is printed via inkjet printing, spin coating, dip coating, blade coating, bar coating, gravure printing, spray coating, or screen printing, and in which said digital logic portion comprises at least one of, a clock generator, a 3-bit binary counter, a line selector, a multiplexor, a ROM, an output register, a data encoding, an anti-collision protocol and an antennae.

18. A system comprising:
a substrate, in which said substrate comprises a metal foil;
a passive layer passivation, in which said passive layer passivation comprises at least a silane coupling agent passivation or a hydrophilic polymer passivation;
a gate electrode layer, wherein said gate electrode layer comprises a first layer deposited on said substrate;
a gate dielectric layer, wherein said gate dielectric layer comprises a layer deposited above said gate electrode layer;
a semiconductor layer, wherein said semiconductor layer is disposed above said gate dielectric layer;
a source contact layer, wherein said source contact layer is deposited above a first portion of said semiconductor layer; and
a drain contact layer, wherein said source contact layer is deposited above a second portion of said semiconductor layer.

19. The system of claim 18, further comprising:
a resistor layer;
a conductor layer;
a dielectric layer disposed above said conductor layer;
a metal line layer disposed above said dielectric layer; and
an encapsulation portion, wherein said encapsulation portion is configured to enclose said layers.

20. A method comprising:
depositing a first layer of a tag on a substrate, in which said first layer comprises at least one of, a metal oxide and carbon based derivative, wherein said first layer is a gate electrode of said tag, and in which said tag comprises at least one of, an RFID tag, RFID label, an NFC tag, a passive tag, and an active tag;
baking said first layer at a predetermined temperature;
depositing a second layer, in which said second layer comprises at least one of said metal oxide and carbon based derivative layer;
annealing said second layer;
treating a surface of said second layer, wherein said surface treatment is configured to enhance conductivity;
depositing a third layer, in which said third layer comprises at least one of, an aluminum oxide, a hafnium oxide, a zirconium oxide, and a silicon dioxide layer;
baking said third layer at a predetermined temperature, wherein said third layer is a gate dielectric of said tag;
depositing a fourth layer, in which said fourth layer comprises at least one of said aluminum oxide, hafnium oxide, zirconium oxide, and silicon dioxide layer.
depositing a fifth layer, in which said fifth layer comprises at least an Indium Gallium Zinc Oxide layer, in which said fifth layer is a semiconductor layer of said tag;
photonic curing said fifth layer; and
depositing a sixth and seventh layer, in which said sixth and seventh layers comprises at least one of, a metal oxide and carbon based derivative, in which said sixth layer is a source contact layer and said seventh layer is a drain contact layer of said tag.
